(19) United States
(12) Patent Application Publication
(10) Pub. No.: US 2026/0150427 A1
(43) Pub. Date: May 28, 2026

(54) PHOTOELECTRIC CONVERSION DEVICE, PHOTODETECTION SYSTEM, AND MOVABLE OBJECT

(71) Applicant: CANON KABUSHIKI KAISHA, Tokyo (JP)

(72) Inventors: ALICE MORIMOTO, Kanagawa (JP); TSUTOMU TANGE, Kanagawa (JP)

(21) Appl. No.: 19/390,015

(22) Filed: Nov. 14, 2025

(30) Foreign Application Priority Data
Nov. 22, 2024 (JP) 2024-203974

(51) Int. Cl. H10F 39/00; H10F 39/18; H10F 77/00; H10F 77/14

(52) U.S. Cl. CPC H10F 39/811; H10F 39/182; H10F 77/14; H10F 77/953

(57) ABSTRACT

A photoelectric conversion device includes a first semiconductor layer provided with a photoelectric conversion element, a second semiconductor layer having a first face and a second face opposite to the first face and provided with an element electrically connected to the photoelectric conversion element on the first face, a through-electrode provided in a through-hole penetrating the second semiconductor layer, a fixed charge containing layer provided in contact with an inner face of the through-hole, a first insulating layer provided between the fixed charge containing layer and the through-electrode, and a second insulating layer including an insulating material and provided in contact with the second face and the fixed charge containing layer.

### BACKGROUND

### Field of the Technology

The present disclosure relates to a photoelectric conversion device, a photodetection system, and a movable object.

### Description of the Related Art

Japanese Patent Laid-Open No. 2023-110873 describes an image sensor configured by stacking a plurality of structures each including a semiconductor substrate. Japanese Patent Laid-Open No. 2023-110873 discloses a through-electrode provided in a through-hole penetrating a semiconductor substrate as one of structures for electrically connecting the plurality of structures.

However, in Japanese Patent Laid-Open No. 2023-110873, no particular consideration is given to the through-hole or the through-electrode, and there is a possibility that noise may occur due to the through-hole or the through-electrode being provided in the semiconductor substrate.

### SUMMARY

The present disclosure is directed to a technique for effectively reducing noise caused by a through-hole or a through-electrode in a photoelectric conversion device configured by stacking a plurality of substrates.

According to one aspect of the present specification, there is provided a photoelectric conversion device including a first semiconductor layer provided with a photoelectric conversion element, a second semiconductor layer having a first face and a second face opposite to the first face and provided with an element electrically connected to the photoelectric conversion element on the first face, a through-electrode provided in a through-hole penetrating the second semiconductor layer, a fixed charge containing layer provided in contact with an inner face of the through-hole, a first insulating layer provided between the fixed charge containing layer and the through-electrode, and a second insulating layer including an insulating material and provided in contact with the second face and the fixed charge containing layer.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram illustrating a configuration example of a photoelectric conversion device according to a first embodiment.

FIG. 2 is a block diagram illustrating another configuration example of the photoelectric conversion device according to the first embodiment.

FIG. 3 is a block diagram illustrating a configuration example of a pixel of the photoelectric conversion device according to the first embodiment.

FIG. 4A, FIG. 4B, and FIG. 4C are diagrams illustrating a basic operation of the photoelectric conversion unit in the photoelectric conversion device according to the first embodiment.

FIG. 5 is a perspective view illustrating a configuration example of the photoelectric conversion device according to the first embodiment.

FIG. 6 is a schematic cross-sectional view illustrating a structure of the photoelectric conversion device according to the first embodiment.

FIG. 7 is a schematic cross-sectional view of a through-electrode in the photoelectric conversion device according to the first embodiment.

FIG. 8A, FIG. 8B, FIG. 8C, FIG. 8D, FIG. 8E, FIG. 8F, FIG. 8G, FIG. 8H, FIG. 8I, FIG. 8J, and FIG. 8K are cross-sectional views illustrating a method of manufacturing the photoelectric conversion device according to the first embodiment.

FIG. 9 is a schematic cross-sectional view illustrating a structure of a photoelectric conversion device according to a second embodiment.

FIG. 10 is a schematic cross-sectional view illustrating a structure of a photoelectric conversion device according to a third embodiment.

FIG. 11 is a schematic cross-sectional view of a through-electrode in the photoelectric conversion device according to the third embodiment.

FIG. 12A, FIG. 12B, FIG. 12C, FIG. 12D, FIG. 12E, and FIG. 12F are cross-sectional views illustrating a method of manufacturing the photoelectric conversion device according to the third embodiment.

FIG. 13 is a schematic cross-sectional view illustrating a structure of a photoelectric conversion device according to a fourth embodiment.

FIG. 14 is a block diagram illustrating a schematic configuration of a photodetection system according to a fifth embodiment.

FIG. 15 is a block diagram illustrating a schematic configuration of a range image sensor according to a sixth embodiment.

FIG. 16 is a schematic diagram illustrating a configuration example of an endoscopic surgical system according to a seventh embodiment.

FIG. 17A, FIG. 17B, and FIG. 17C are schematic diagrams illustrating a configuration example of a movable object according to an eighth embodiment.

FIG. 18 is a block diagram illustrating a schematic configuration of a photodetection system according to the eighth embodiment.

FIG. 19 is a flowchart illustrating an operation of the photodetection system according to the eighth embodiment.

FIG. 20A and FIG. 20B are schematic diagrams illustrating a schematic configuration of a photodetection system according to a ninth embodiment.

### DESCRIPTION OF THE EMBODIMENTS

Hereinafter, embodiments of the present disclosure will be described in detail with reference to the accompanying drawings. Note that the following embodiments do not limit the technology according to the claims. Although multiple features are described in the embodiments, not all of these multiple features are essential to the present disclosure, and multiple features may be arbitrarily combined. In the following description, a term indicating a specific direction or position (for example, “up”, “down”, “right”, “left” and other terms including those terms) is used as necessary. The use of these terms is to facilitate understanding of the embodiments with reference to the drawings, and the technical scope of the present disclosure is not limited by the meanings of these terms. In addition, sizes and positional relationships of members illustrated in the drawings may be exaggerated for clarity of description.

In each of the embodiments described below, a photoelectric conversion device for imaging purposes will be mainly described as an example of a semiconductor device. However, the embodiments are not limited to photoelectric conversion devices for imaging purposes and may be applied to other semiconductor devices. For example, other examples of the photoelectric conversion device include a ranging device (a device for distance measurement and the like using a focus detection or a time of flight (TOF)), and a photometric device (a device for measuring the amount of incident light).

### First Embodiment

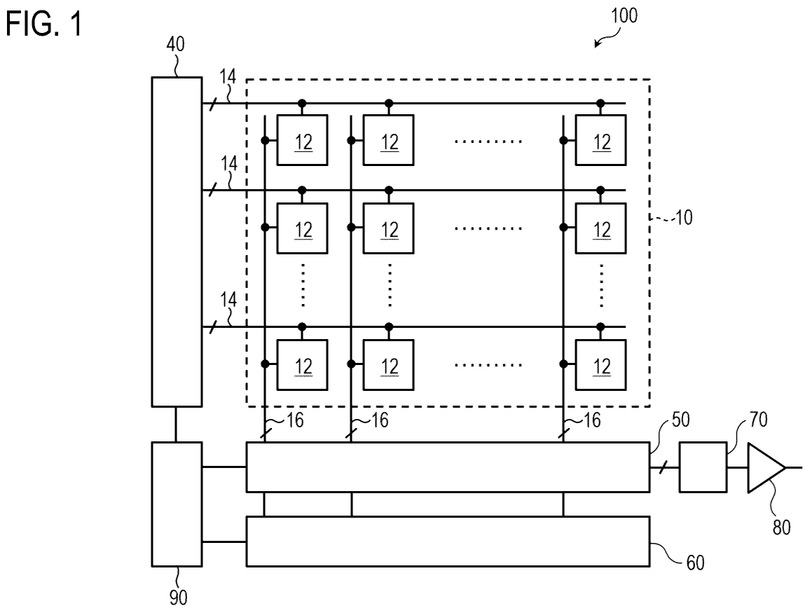

A schematic configuration of a photoelectric conversion device according to a first embodiment will be described with reference to FIG. 1. FIG. 1 is a block diagram illustrating a schematic configuration of a photoelectric conversion device according to the present embodiment.

As illustrated in FIG. 1, the photoelectric conversion device 100 according to the present embodiment includes a pixel region 10, a vertical scanning circuit unit 40, a readout circuit unit 50, a horizontal scanning circuit unit 60, a digital front end (DFE) 70, a transmitter circuit unit (TX) 80, and a control pulse generation unit 90.

The pixel region 10 is provided with a plurality of pixels 12 arranged in an array so as to form a plurality of rows and a plurality of columns. As described later, each of the plurality of pixels 12 may include a photoelectric conversion unit including a photoelectric conversion element and a signal processing unit that processes a signal output from the photoelectric conversion unit. The number of pixels 12 constituting the pixel region 10 is not particularly limited. For example, like a general digital camera, the pixel region 10 may be constituted by a plurality of pixels 12 arranged in an array of several thousand rows ×several thousand columns. Alternatively, the pixel region 10 may include a plurality of pixels 12 arranged in one row or one column. Alternatively, one pixel 12 may constitute the pixel region 10.

In each row of the pixel array of the pixel region 10, a control line 14 is arranged so as to extend in a first direction (lateral direction in FIG. 1). Each of the control lines 14 is connected to the pixels 12 arranged in the first direction on the corresponding row, respectively, and forms a signal line common to these pixels 12. The first direction in which the control lines 14 extend may be referred to as a row direction or a horizontal direction. Each of the control lines 14 may include a plurality of signal lines for supplying a plurality of types of control signals to the pixels 12.

Further, in each column of the pixel array of the pixel region 10, an output line 16 is arranged so as to extend in a second direction (vertical direction in FIG. 1) intersecting the first direction. Each of the output lines 16 is connected to the pixels 12 arranged in the second direction on the corresponding column, respectively, and forms a signal line common to these pixels 12. The second direction in which the output lines 16 extend may be referred to as a column direction or a vertical direction. Each of the output lines 16 may include a plurality of signal lines for transferring a digital signal of a plurality of bits output from the pixel 12 on a bit-by-bit basis.

The control line 14 of each row is connected to the vertical scanning circuit unit 40. The vertical scanning circuit unit 40 is a control circuit having a function of generating a control signal for driving the pixels 12 in response to a control signal output from the control pulse generation unit 90 and supplying the generated control signal to the pixels 12 via the control line 14. A logic circuit such as a shift register or an address decoder may be used as the vertical scanning circuit unit 40. The vertical scanning circuit unit 40 sequentially scans the pixels 12 in the pixel region 10 row by row to output the pixel signals of the pixels 12 to the readout circuit unit 50 via the output lines 16.

The output line 16 of each column is connected to the readout circuit unit 50. The readout circuit unit 50 includes a plurality of holding units (not illustrated) provided corresponding to each column of the pixel array of the pixel region 10 and has a function of holding the pixel signals of the pixels 12 of the respective columns output from the pixel region 10 in units of rows via the output lines 16 in the holding units of the corresponding columns.

The horizontal scanning circuit unit 60 is a control circuit having a function of generating a control signal for reading out a pixel signal from the holding unit of each column of the readout circuit unit 50 in response to a control signal output from the control pulse generation unit 90 and supplying the generated control signal to the readout circuit unit 50. A logic circuit such as a shift register or an address decoder may be used as the horizontal scanning circuit unit 60. The horizontal scanning circuit unit 60 sequentially scans the holding units of the respective columns of the readout circuit unit 50 to sequentially output the pixel signals held in the holding units to the DFE 70.

The DFE 70 is a signal processing circuit unit that performs predetermined digital signal processing on the pixel signal output from the readout circuit unit 50. The DFE 70 sequentially outputs the pixel signals subjected to the digital signal processing to the TX 80.

The TX 80 is a circuit unit for outputting the pixel signal output from the readout circuit unit 50 to the outside of the photoelectric conversion device 100 and includes an external interface circuit. The external interface circuit included in the TX 80 is not particularly limited. As the external interface circuit, for example, a SERializer/DESerializer (SerDes) transmission circuit may be applied. Examples of the SerDes transmission circuit include a low voltage differential signaling (LVDS) circuit and a scalable low voltage signaling (SLVS) circuit.

The control pulse generation unit 90 is a control circuit for generating a control signal for controlling the operations and timings thereof of the vertical scanning circuit unit 40, the readout circuit unit 50, and the horizontal scanning circuit unit 60, and supplying the control signal to each functional block. At least a part of the control signals for controlling the operations and timings of the vertical scanning circuit unit 40, the readout circuit unit 50, and the horizontal scanning circuit unit 60 may be supplied from the outside of the photoelectric conversion device 100.

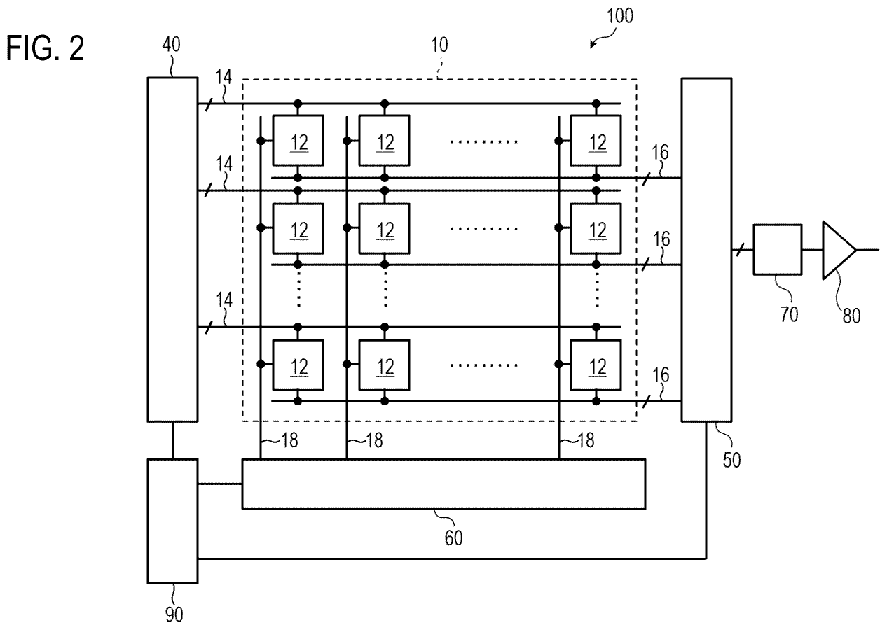

The connection mode of each functional block of the photoelectric conversion device 100 is not limited to the configuration example of FIG. 1 and may be configured as illustrated in, e.g., FIG. 2.

In the configuration example of FIG. 2, the output line 16 extending in the first direction is arranged in each row of the pixel array of the pixel region 10. Each of the output lines 16 is connected to the pixels 12 arranged in the first direction on the corresponding row, respectively, and forms a signal line common to these pixels 12. A control line 18 extending in the second direction is arranged in each column of the pixel array of the pixel region 10. Each of the control lines 18 is connected to the pixels 12 arranged in the second direction on the corresponding column, respectively, and forms a signal line common to these pixels 12.

The control line 18 of each column is connected to the horizontal scanning circuit unit 60. The horizontal scanning circuit unit 60 generates a control signal for reading out the pixel signal from the pixel 12 in response to a control signal output from the control pulse generation unit 90 and supplies the generated control signal to the pixel 12 via the control line 18. Specifically, the horizontal scanning circuit unit 60 sequentially scans the plurality of pixels 12 in the pixel region 10 in units of columns to output the pixel signals of the pixels 12 in the respective rows belonging to the selected column to the output lines 16.

The output line 16 of each row is connected to the readout circuit unit 50. The readout circuit unit 50 includes a plurality of holding units (not illustrated) provided corresponding to the respective rows of the pixel array of the pixel region 10 and has a function of holding the pixel signals of the pixels 12 of the respective rows output from the pixel region 10 in units of columns via the output lines 16 in the holding units of the corresponding rows.

The readout circuit unit 50 sequentially outputs the pixel signals held in the holding units of the respective rows to the DFE 70 in response to a control signal output from the control pulse generation unit 90.

Other configurations in the configuration example of FIG. 2 may be the same as those in the configuration example of FIG. 1.

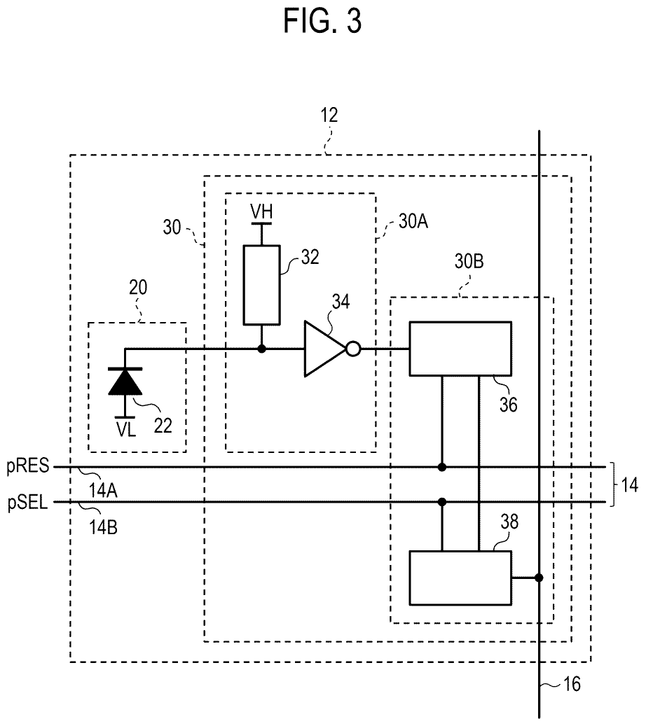

FIG. 3 is a block diagram illustrating a configuration example of the pixel of the photoelectric conversion device according to the present embodiment. As illustrated in FIG. 3, each of the plurality of pixels 12 includes a photoelectric conversion unit 20 and a signal processing unit 30. The photoelectric conversion unit 20 includes a photoelectric conversion element 22 and outputs a signal according to incident light. The signal processing unit 30 is a signal processing circuit that processes a signal output from the photoelectric conversion unit 20. The signal processing unit 30 includes a functional block 30A including a quenching circuit 32 and a waveform shaping circuit 34, and a functional block 30B including a selection circuit 38 and a processing circuit 36. In the case of the pixel configuration illustrated in FIG. 3, the control line 14 of each row may include a signal line 14A to which a control signal pRES is supplied from the vertical scanning circuit unit 40 and a signal line 14B to which a control signal pSEL is supplied from the vertical scanning circuit unit 40.

The photoelectric conversion element 22 may be an avalanche photodiode (hereinafter referred to as “APD”). An anode of the APD constituting the photoelectric conversion element 22 is connected to a node to which a voltage VL is supplied. A cathode of the APD constituting the photoelectric conversion element 22 is connected to one terminal of the quenching circuit 32. A connection node between the photoelectric conversion element 22 and the quenching circuit 32 is an output node of the photoelectric conversion unit 20. The other terminal of the quenching circuit 32 is connected to a node to which a voltage VH higher than the voltage VL is supplied. The voltage VL and the voltage VH are set so that a reverse bias voltage sufficient for the APD to perform the avalanche multiplication operation is applied. In one example, a negative high voltage is applied as the voltage VL, and a positive voltage comparable to a power supply voltage is applied as the voltage VH. For example, the voltage VL is −30 V, and the voltage VH is 1 V.

The photoelectric conversion element 22 may be configured by an APD as described above. When a reverse bias voltage sufficient to perform the avalanche multiplication operation is supplied to the APD, carriers generated by light incident on the APD cause avalanche multiplication, and an avalanche current is generated. The operation modes in a state where the reverse bias voltage is supplied to the APD include a Geiger mode and a linear mode. The Geiger mode is an operation mode in which a voltage applied between the anode and the cathode is set to a reverse bias voltage larger than a breakdown voltage of the APD. The linear mode is an operation mode in which a voltage applied between the anode and the cathode is set to a reverse bias voltage close to or lower than the breakdown voltage of the APD. An APD that operates in Geiger mode is referred to as single-photon avalanche diode (SPAD). The APD constituting the photoelectric conversion element 22 may be operated in the linear mode or in the Geiger mode, but the SPAD having a larger potential difference than the APD in the linear mode and having a remarkable improvement effect of the signal-to-noise ratio is more preferable.

Although the anode of the APD is set to a fixed potential and a signal is extracted from the cathode side in the circuit configuration of FIG. 3, the cathode of the APD may be set to a fixed potential and a signal may be extracted from the anode side. In the former case, the signal charge is an electron. In the latter case, the signal charge is a hole. Further, in the present embodiment, a case where one node of the APD is set to a fixed potential will be described, but the potentials of both nodes may vary.

The quenching circuit 32 has a function of converting a change in the avalanche current generated in the photoelectric conversion element 22 into a voltage signal. In addition, the quenching circuit 32 functions as a load circuit (quenching circuit) at the time of signal multiplication by avalanche multiplication and has a function of suppressing avalanche multiplication by reducing a voltage applied to the photoelectric conversion element 22. The operation in which the quenching circuit 32 suppresses avalanche multiplication is called a quenching operation. In addition, the quenching circuit 32 has a function of returning the voltage supplied to the photoelectric conversion element 22 to the voltage VH by flowing a current corresponding to the voltage drop due to the quenching operation. The operation of returning the voltage supplied from the quenching circuit 32 to the photoelectric conversion element 22 to the voltage VH is called a recharge operation. The quenching circuit 32 may be configured by a resistor, a MOS transistor, or the like.

The waveform shaping circuit 34 includes an input node to which the output signal of the photoelectric conversion unit 20 is supplied and an output node. The waveform shaping circuit 34 has a function of converting an analog signal supplied from the photoelectric conversion unit 20 into a pulse signal. The waveform shaping circuit 34 may be configured by a logic circuit including a NOT circuit (inverter circuit), a NOR circuit, a NAND circuit, and the like. The output node of the waveform shaping circuit 34 is connected to the processing circuit 36.

The processing circuit 36 has an input node to which the output signal of the waveform shaping circuit 34 is supplied, an input node connected to the control line 14, and an output node. The processing circuit 36 has a function of performing predetermined signal processing on the output signal of the waveform shaping circuit 34 and holding the processed signal or the processing result. Although not particularly limited, the processing circuit 36 may be, for example, a counter circuit. In this case, the processing circuit 36 counts pulses superimposed on the signal output from the waveform shaping circuit 34 and holds a count value which is a count result. The signal supplied from the vertical scanning circuit unit 40 to the processing circuit 36 via the control line 14 may include an enable signal for controlling a pulse counting period (exposure period), a reset signal for resetting a count value held by the processing circuit 36, and the like. FIG. 3 illustrates, as an example, a reset signal (control signal pRES) supplied via the signal line 14A. The output node of the processing circuit 36 is connected to the selection circuit 38.

The selection circuit 38 has a function of switching an electrical connection state (connection or non-connection) between the processing circuit 36 and the output line 16. The selection circuit 38 switches the connection state between the processing circuit 36 and the output line 16 according to a selection signal supplied from the vertical scanning circuit unit 40 via the control line 14 (or a selection signal supplied from the horizontal scanning circuit unit 60 via the control line 18 in the configuration example of FIG. 2). FIG. 3 illustrates, as an example, a selection signal (control signal pSEL) supplied via the signal line 14B. The processing circuit 36 may include buffer circuit for outputting signals.

The pixel 12 is typically a unit structure that outputs a pixel signal for forming an image. However, in the case of aiming at distance measurement using a time of flight (TOF) method, the pixel 12 does not necessarily need to be a unit structure that outputs a pixel signal for forming an image. That is, the pixel 12 may be a unit structure that outputs a signal for measuring the time at which light arrives and the amount of light.

One signal processing unit 30 is not necessarily provided for each pixel 12, and one signal processing unit 30 may be provided for a plurality of pixels 12. In this case, the signal processing of the plurality of pixels 12 may be sequentially performed using one signal processing unit 30.

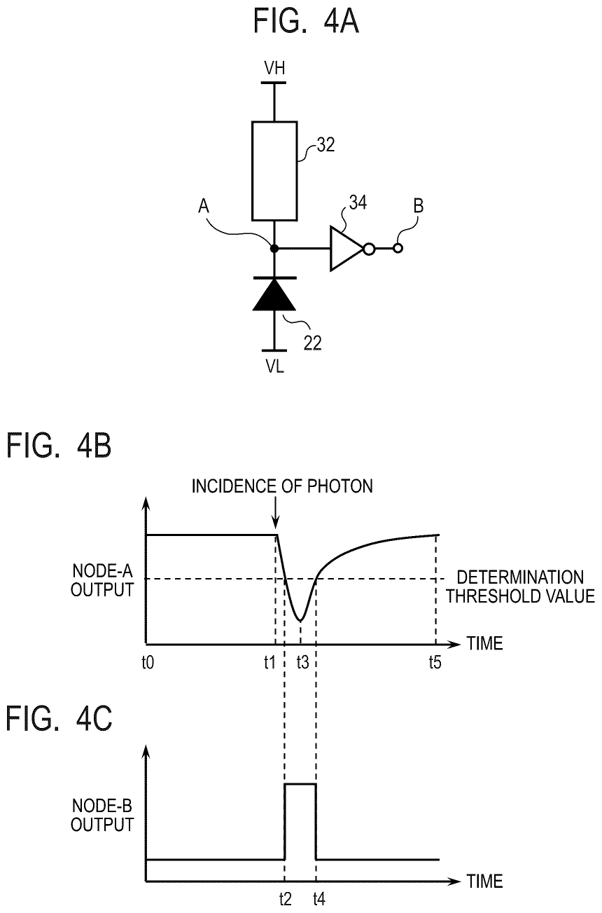

Next, a basic operation of the photoelectric conversion unit 20 in the photoelectric conversion device according to the present embodiment will be described with reference to FIG. 4A to FIG. 4C. FIG. 4A to FIG. 4C are diagrams illustrating the basic operation of the photoelectric conversion element 22, the quenching circuit 32, and the waveform shaping circuit 34 in the photoelectric conversion device according to the present embodiment. FIG. 4A is a circuit diagram of the photoelectric conversion element 22, the quenching circuit 32, and the waveform shaping circuit 34. FIG. 4B illustrates the waveform of the signal at the input node (node-A) of the waveform shaping circuit 34. FIG. 4C illustrates the waveform of the signal at the output node (node-B) of the waveform shaping circuit 34. Here, in order to simplify the description, it is assumed that the waveform shaping circuit 34 is configured by an inverter circuit.

At time t0, a reverse bias voltage having a potential difference corresponding to (VH−VL) is applied to the photoelectric conversion element 22. Although a reverse bias voltage sufficient to cause avalanche multiplication is applied between the anode and the cathode of the APD constituting the photoelectric conversion element 22, carriers serving as seeds of avalanche multiplication do not exist in a state where photons are not incident on the photoelectric conversion element 22. Therefore, avalanche multiplication does not occur in the photoelectric conversion element 22, and no current flows through the photoelectric conversion element 22.

At the subsequent time t1, it is assumed that a photon is incident on the photoelectric conversion element 22. When a photon enters the photoelectric conversion element 22, an electron-hole pair is generated by photoelectric conversion, avalanche multiplication occurs using these carriers as seeds, and an avalanche current flows through the photoelectric conversion element 22. When this avalanche current flows through the quenching circuit 32, a voltage drop occurs due to the quenching circuit 32, and the voltage of the node-A starts to drop. When the voltage drop amount of the node-A becomes large and the avalanche multiplication is stopped at time t3, the voltage level of the node-A no longer drops.

When the avalanche multiplication in the photoelectric conversion element 22 is stopped, a current that compensates for the voltage drop flows from the node to which the voltage VL is supplied to the node-A through the photoelectric conversion element 22, and the voltage of the node-A gradually increases. Thereafter, at time t5, the node-A is settled to the original voltage level.

The waveform shaping circuit 34 binarizes the signal input from the node-A according to a predetermined determination threshold value, and outputs the signal from the node-B. Specifically, the waveform shaping circuit 34 outputs a low-level signal from the node-B when the voltage level of the node-A exceeds the determination threshold value, and outputs a high-level signal from the node-B when the voltage level of the node-A is equal to or less than the determination threshold value. For example, as illustrated in FIG. 4B, it is assumed that the voltage of the node-A is equal to or lower than the determination threshold value in the period from the time t2 to the time t4. In this case, as illustrated in FIG. 4C, the signal level at the node-B becomes low-level in the period from the time t0 to the time t2 and the period from the time t4 to the time t5, and becomes high-level in the period from the time t2 to the time t4.

Thus, the analog signal input from the node-A is waveform-shaped into a digital signal by the waveform shaping circuit 34. A pulse signal output from the waveform shaping circuit 34 in response to incidence of a photon on the photoelectric conversion element 22 is a photon detection pulse signal.

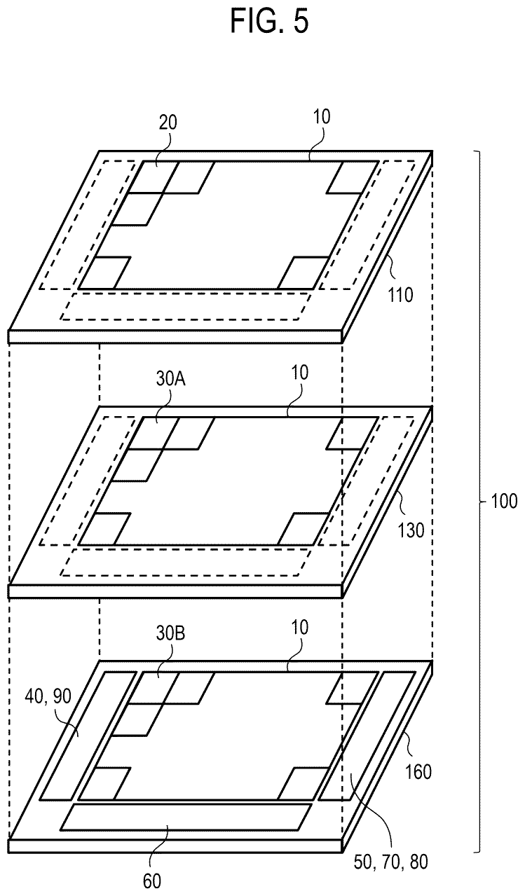

The photoelectric conversion device 100 according to the present embodiment may be configured as a stacked-type photoelectric conversion device in which a plurality of substrates is stacked. For example, as illustrated in FIG. 5, the photoelectric conversion device 100 may be configured by stacking three substrates of the sensor substrate 110, the circuit substrate 130, and the circuit substrate 160 and electrically connecting the substrates to each other.

In the case of the configuration example of FIG. 5, at least the photoelectric conversion unit 20 among the constituent elements of the pixel 12 may be arranged on the sensor substrate 110. A functional block 30A of the signal processing unit 30 among the constituent elements of the pixels 12 may be arranged on the circuit substrate 130. A functional block 30B of the signal processing unit 30 among the constituent elements of the pixels 12 may be arranged on the circuit substrate 160. Each of the sensor substrate 110, the circuit substrate 130, and the circuit substrate 160 may be provided with the pixel region 10 so as to overlap each other in a plan view. The photoelectric conversion unit 20, the functional block 30A, and the functional block 30B of each of the plurality of pixels 12 configuring the pixel region 10 may be provided on the sensor substrate 110, the circuit substrate 130, and the circuit substrate 160, respectively, so as to overlap each other in a plan view. In this specification, the plan view refers to a view from a direction perpendicular to the light incident surface of the sensor substrate 110. When the light incident surface of the semiconductor layer is a rough surface as viewed microscopically, a plan view is defined with reference to the light incident surface of the semiconductor layer as viewed macroscopically. The photoelectric conversion unit 20 and the functional block 30A, and the functional block 30A and the functional block 30B are electrically connected to each other via interconnections (not illustrated) provided for each pixel 12.

The circuit substrates 130 and 160 may further include a vertical scanning circuit unit 40, a readout circuit unit 50, a horizontal scanning circuit unit 60, a DFE 70, a TX 80, and a control pulse generation unit 90. The vertical scanning circuit unit 40, the readout circuit unit 50, the horizontal scanning circuit unit 60, the DFE 70, the TX 80, and the control pulse generation unit 90 may be arranged around the pixel region 10 on the circuit substrates 130 and 160. Each of the vertical scanning circuit unit 40, the readout circuit unit 50, the horizontal scanning circuit unit 60, the DFE 70, the TX 80, and the control pulse generation unit 90 may be provided on one of the circuit substrates 130 and 160 or may be provided by being divided into the circuit substrates 130 and 160.

By configuring the stacked-type photoelectric conversion device 100, it is possible to increase the degree of integration of elements and achieve higher functionality. In particular, by arranging the photoelectric conversion unit 20 and the signal processing unit 30 on different substrates, the photoelectric conversion elements 22 may be arranged at high density without sacrificing the light receiving area of the photoelectric conversion elements 22, and the photon detection efficiency may be improved. In addition, by arranging the functional block 30A and the functional block 30B of the signal processing unit 30 on different substrates, it is possible to achieve high integration and high functionality of the processing circuit 36 constituting the functional block 30B while arranging the photoelectric conversion elements 22 at high density.

Although FIG. 5 illustrates a configuration in which three substrates of the sensor substrate 110, the circuit substrate 130, and the circuit substrate 160 are stacked, a configuration in which the circuit of the circuit substrate 130 and the circuit of the circuit substrate 160 are arranged on one substrate and two substrates are stacked may be employed. Alternatively, a structure in which four or more substrates are stacked may be employed.

In FIG. 5, a diced chip is assumed as the sensor substrate 110 and the circuit substrates 130 and 160, but the sensor substrate 110 and the circuit substrates 130 and 160 are not limited to chips. For example, each of the sensor substrate 110 and the circuit substrates 130 and 160 may be a wafer. In addition, the sensor substrate 110 and the circuit substrates 130 and 160 may be stacked in a wafer state and then diced or may be stacked and bonded after being formed into chips.

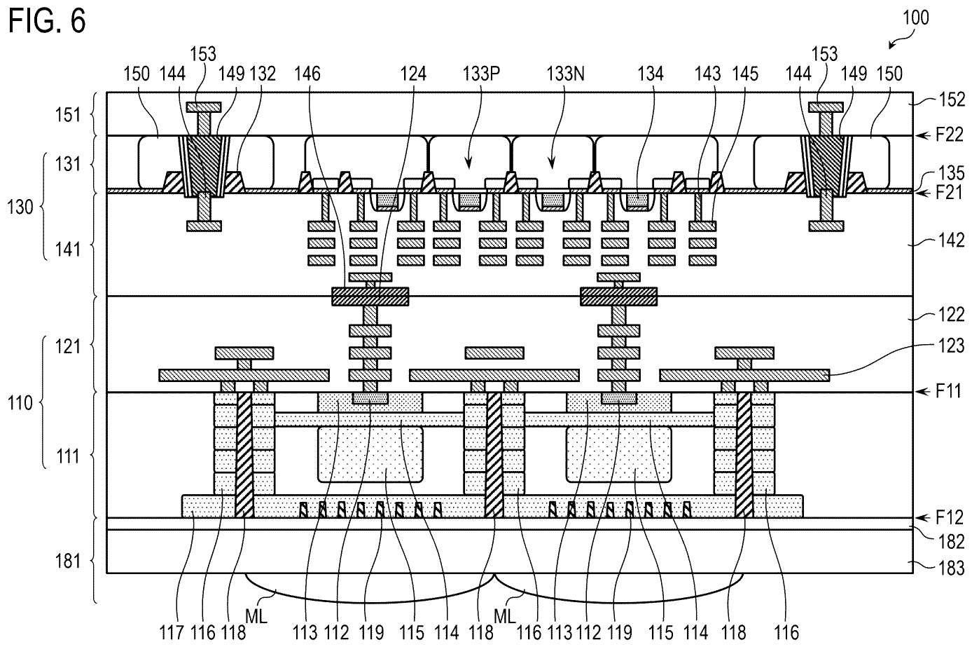

FIG. 6 is a schematic cross-sectional view illustrating a more specific configuration example of the photoelectric conversion device according to the present embodiment. FIG. 6 illustrates an example of a photoelectric conversion device configured by stacking two substrates of the sensor substrate 110 and the circuit substrate 130. The sensor substrate 110 includes a semiconductor layer 111 having a first face F11 and a second face F12 opposite to the first surface F11, and an interconnection structure layer 121 provided on a side of the first face F11 of the semiconductor layer 111. The circuit substrate 130 includes a semiconductor layer 131 having a first face F21 and a second face F22 opposite to the first face F21, and an interconnection structure layer 141 provided on a side of the first face F21 of the semiconductor layer 131.

At least the photoelectric conversion elements 22 among the constituent elements of the plurality of pixels 12 may be provided in the semiconductor layer 111. FIG. 6 illustrates the photoelectric conversion elements 22 of two adjacent pixels 12 among the plurality of pixels 12 constituting the pixel region 10. Each of the photoelectric conversion elements 22 is configured to supply a drive voltage from the side of the first face F11 and output a photon detection pulse signal to the side of the first face F11. Each of the photoelectric conversion elements 22 is configured to detect light incident from the side of the second face F12.

The structure of the photoelectric conversion element 22 is not particularly limited. Here, as an example, it is assumed that a charge collection type SPAD including n-type semiconductor regions 112, 113, and 115 and p-type semiconductor regions 114, 116, and 117 is provided in the semiconductor layer 111 having a low impurity concentration.

The semiconductor layer 111 is obtained by thinning a semiconductor substrate, for example, a single crystalline silicon substrate, and contains an n-type impurity or a p-type impurity at a predetermined concentration. In the present embodiment, as an example, the semiconductor layer 111 obtained by thinning an n-type silicon substrate having a low impurity concentration is assumed.

The p-type semiconductor region 117 is provided on the side of the second face F12 of the semiconductor layer 111 in a cross-sectional view. Note that in this specification, the cross-sectional view refers to a view of a cross-section of a semiconductor layer perpendicular to a light incident surface viewed from a normal direction. The p-type semiconductor region 117 is provided over the entire region in which the photoelectric conversion element 22 is arranged and overlaps the n-type semiconductor regions 112 and 113 and the p-type semiconductor regions 114, 115, and 116 in a plan view. When the back illuminated photoelectric conversion device is configured, the p-type semiconductor region 117 is preferably arranged so as to be in contact with the second face F12. With this configuration, it is possible to prevent generation of a dark current on the second face F12. The p-type semiconductor region 116 is provided at a boundary portion between the photoelectric conversion elements 22 of the adjacent pixels 12. That is, the p-type semiconductor region 116 is provided so as to surround each of the regions in which the photoelectric conversion elements 22 are arranged in the plan view. The p-type semiconductor region 116 is provided from the first face F11 of the semiconductor layer 120 to a depth at which the p-type semiconductor region 117 is arranged.

N-type semiconductor regions 112, 113, and 115 and a p-type semiconductor region 114 are provided inside the region surrounded by the p-type semiconductor regions 116 and 117. The n-type semiconductor region 112 is a region constituting the cathode of the APD and is provided on the side of the first face F11 of the semiconductor layer 111 so as to be separated from the p-type semiconductor region 116. The n-type semiconductor region 113 is provided so as to surround the n-type semiconductor region 112. The p-type semiconductor region 114 is a region constituting the anode of the APD and is provided closer to the second face F12 than the n-type semiconductor regions 112 and 113. The p-type semiconductor region 114 is in contact with the p-type semiconductor region 116 in a peripheral portion in the plan view. The n-type semiconductor region 115 is provided between the p-type semiconductor region 114 and the p-type semiconductor region 117.

An isolation structure 118 may be further provided inside the p-type semiconductor region 116. The isolation structure 118 has a function of preventing light from leaking into the adjacent photoelectric conversion element 22 and is preferably a wall-like body surrounding each region in which the photoelectric conversion element 22 is arranged. The isolation structure 118 may be configured by, for example, burying an insulating member or a metal member in a groove formed in the semiconductor layer 111. Although the isolation structure 118 is provided from the first face F11 to the second face F12 of the semiconductor layer 111 in the configuration example of FIG. 6, the isolation structure 118 may not necessarily reach the second face F12 from the first face F11.

The concave-convex structure 119 may be further provided on the second face F12 of the semiconductor layer 111. The concave-convex structure 119 has a function of scattering light incident from the side of the second face F12 of the semiconductor layer 111, and a pattern constituting the concave-convex structure 119 is not particularly limited as long as it has a function of scattering light incident from the side of the second face F12. The concave-convex structure 119 may be configured by, for example, burying an insulating member in a groove formed on the second face F12 of the semiconductor layer 111.

The interconnection structure layer 121 may include an insulating layer 122 and one or a plurality of interconnection layers arranged in the insulating layer 122. The one or the plurality of interconnection layers include an interconnection 123 electrically connected to the photoelectric conversion element 22 and an interconnection 124 formed of the uppermost-level interconnection layer that is most distant from the first face F11.

The semiconductor layer 131 is provided with elements constituting the signal processing unit 30, the vertical scanning circuit unit 40, the readout circuit unit 50, the horizontal scanning circuit unit 60, the DFE 70, the TX 80, and the control pulse generation unit 90 of the pixel 12. FIG. 6 illustrates an n-channel transistor 133N and a p-channel transistor 133P as examples of the elements constituting these functional blocks. At least a part of these elements is electrically connected to the photoelectric conversion element 22 provided in the semiconductor layer 111. On the first face F21 of the semiconductor layer 131, an element isolation portion 132 for isolating these elements is provided. A silicide layer 135 is provided on the active region of the first face F21 defined by the element isolation portion 132 and on the gate electrodes 134 of the n-channel transistor 133N and the p-channel transistor 133P. A through-electrode 149 is provided in the semiconductor layer 131. The through-electrode 149 is provided in a through-hole penetrating between the first face F21 and the second face F22 of the semiconductor layer 131.

The interconnection structure layer 141 may include an insulating layer 142 and one or a plurality of interconnection layers arranged in the insulating layer 142. The one or the plurality of interconnection layers include an interconnection 145 connected to the element in the semiconductor layer 131 via a contact plug 143, a contact plug 144 connected to the through-electrode 149, and an interconnection 146 formed of the uppermost-level interconnection layer that is most distant from the first face F21.

The sensor substrate 110 and the circuit substrate 130 are bonded to each other in a face-to-face manner such that the first face F11 of the semiconductor layer 111 on which the interconnection structure layer 121 is arranged faces the first face F21 of the semiconductor layer 131 on which the interconnection structure layer 141 is arranged. That is, the bonding surface between the sensor substrate 110 and the circuit substrate 130 is formed by the interface between the interconnection structure layer 121 and the interconnection structure layer 141. The electrical connection between the sensor substrate 110 and the circuit substrate 130 may be formed by metal bonding between the uppermost-level metal interconnection (interconnection 124) constituting the interconnection structure layer 121 and the uppermost-level metal interconnection (interconnection 146) constituting the interconnection structure layer 141.

An interconnection structure layer 151 is provided on the side of the second face F22 of the semiconductor layer 131. The interconnection structure layer 151 includes an insulating layer 152 and one or a plurality of interconnection layers arranged in the insulating layer 152. The one or the plurality of interconnection layers include an interconnection 153 electrically connected to the through-electrode 149. The interconnection 153 is electrically connected to the contact plug 144 provided in the interconnection structure layer 141 via the through-electrode 149. A circuit substrate different from the circuit substrate 130 may be bonded instead of the interconnection structure layer 151.

An optical structure layer 181 is provided on the side of the second face F12 of the semiconductor layer 111. The optical structure layer 181 may include, for example, a pinning film 182, a planarization layer 183, and a microlens layer including a plurality of microlenses ML. The optical structure layer 181 may further include a filter layer (not illustrated). Various optical filters such as a color filter, an infrared cut filter, and a monochrome filter may be applied to the filter layer.

The photoelectric conversion device according to the present embodiment is a photoelectric conversion device configured to detect light incident from the side of the second face F12 which is the back surface side of the semiconductor layer 111 through the optical structure layer 181, that is, a so-called back illuminated photoelectric conversion device. However, the photoelectric conversion device according to the present disclosure may be configured as a photoelectric conversion device configured to detect light incident from the side of the first face F11 which is the front surface side of the semiconductor layer 111, that is, a so-called front illuminated photoelectric conversion device.

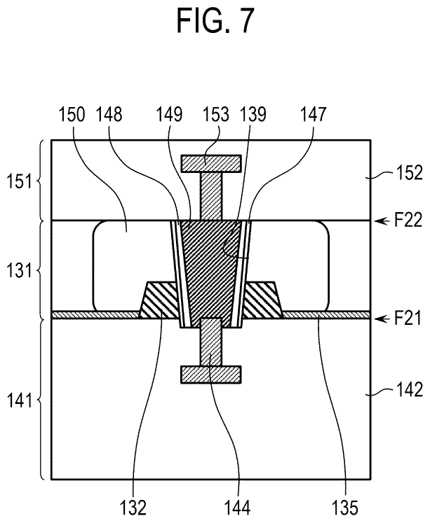

FIG. 7 is an enlarged cross-sectional view of a portion where the through-electrode 149 is provided. The semiconductor layer 131 is provided with a through-hole 139 penetrating therethrough. When the element isolation portion 132 is provided on the side of the first face F21 of the semiconductor layer 131, the through-hole 139 may be provided so as to penetrate the element isolation portion 132. In a portion of the semiconductor layer 131 where the through-hole 139 is provided, a semiconductor region 150 is provided from the side of the first face F21 to the side of the second face F22. In other words, the periphery of the through-hole 139 in the portion penetrating the semiconductor layer 131 is constituted by the semiconductor region 150. By applying a fixed potential to the semiconductor region 150, the influence of the potential change of the through-electrode 149 may be electrostatically shielded, and the electrical influence on the transistor arranged around the through-electrode 149 may be reduced. Note that the semiconductor region 150 may be an n-type semiconductor region or a p-type semiconductor region. In the case where the semiconductor region 150 and the well region of the transistor adjacent to the semiconductor region 150 are regions of different conductivity types, dark electrons generated when the through-hole 139 is formed may be prevented from leaking to the adjacent transistor. Note that a low impurity concentration region may be provided between the semiconductor region 150 and the n-channel transistor 133N. By providing the low impurity concentration region, it is possible to reduce the p-n junction capacitance between the semiconductor region 150 and the n-channel transistor 133N, and it is possible to reduce the electrical influence on the transistor arranged around the through-electrode 149, which may be caused by the potential change of the through-electrode 149. Note that a low impurity concentration region may be provided between the semiconductor region 150 and the p-channel transistor 133P. By providing the low impurity concentration region, it is possible to reduce the p-n junction capacitance between the semiconductor region 150 and the p-channel transistor 133P, and it is possible to reduce the electrical influence on the transistor arranged around the through-electrode 149, which may be caused by the potential change of the through-electrode 149.

A fixed charge containing layer 147, an insulating layer 148, and the through-electrode 149 are provided in the through-hole 139. The fixed charge containing layer 147 is provided so as to be in contact with the inner surface of the through-hole 139. The insulating layer 148 is provided along the inner surface of the through-hole 139 in which the fixed charge containing layer 147 is provided. The insulating layer 148 is preferably thicker on the side of the first face F21 than on the side of the second face F22. The through-electrode 149 is provided so as to fill the through-hole 139 in which the fixed charge containing layer 147 and the insulating layer 148 are provided. The through-electrode 149 is electrically connected to the contact plug 144 as a connection member provided as a part of the interconnection structure layer 141 at an end portion of the semiconductor layer 131 on the side of the first face F21. The through-electrode 149 is electrically connected to the interconnection 153 provided as a part of the interconnection structure layer 151 at the end portion of the semiconductor layer 131 on the side of the second face F22.

The fixed charge containing layer 147 is a layer having fixed charges, for example, negative fixed charges. The fixed charge containing layer 147 may be formed of, for example, hafnium oxide, zirconium oxide, aluminum oxide, titanium oxide, tantalum oxide, or the like. By providing the fixed charge containing layer 147 on the inner surface of the through-hole 139, holes may be induced in the vicinity of the inner surface of the through-hole 139. By recombining dark electrons caused by etching damage or the like at the time of forming the through-hole 139 with the holes, it is possible to reduce generation of electrons contributing to a noise signal. Note that the fixed charge containing layer 147 may be a layer having positive fixed charges. In this case, electrons may be induced in the vicinity of the inner surface of the through-hole 139 by providing the fixed charge containing layer 147 on the inner surface of the through-hole 139. By recombining holes caused by etching damage or the like at the time of forming the through-hole 139 with the electrons, it is possible to reduce generation of holes contributing to a noise signal.

On the other hand, the fixed charge containing layer 147 is not in contact with the second face F22 of the semiconductor layer 131. Instead, the insulating layer 152 is in contact with the second face F22 of the semiconductor layer 131. This is because if the film having fixed charges is in contact with the second face F22 of the semiconductor layer 131, the depletion region of the semiconductor element (e.g., MOS transistor) provided in the semiconductor layer 131 and the fixed charge containing layer 147 may come into contact with each other, and a leakage current may be generated between the semiconductor elements.

From such a viewpoint, as the insulating layer 152, an insulating material containing silicon such as, for example, silicon oxide (SiO), silicon nitride (SiN), silicon oxynitride (SiON), silicon carbide (SiC), or silicon carbonitride (SiCN) may be preferably used. At least a portion of the insulating layer 152 in contact with the second face F22 of the semiconductor layer 131 may be formed of any of these insulating materials that do not contain fixed charges. Like the insulating layer 152, the insulating layer 148 may be formed of an insulating material containing silicon. The through-electrode 149 may be made of a conductive material such as tungsten, aluminum, or copper.

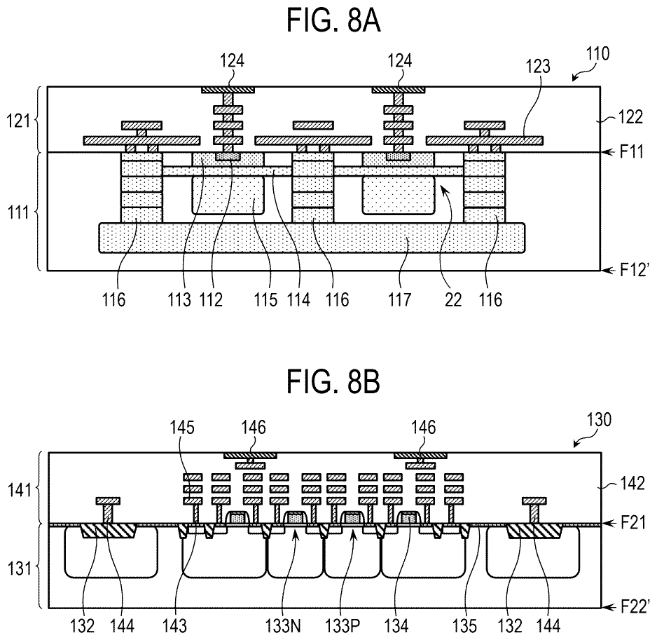

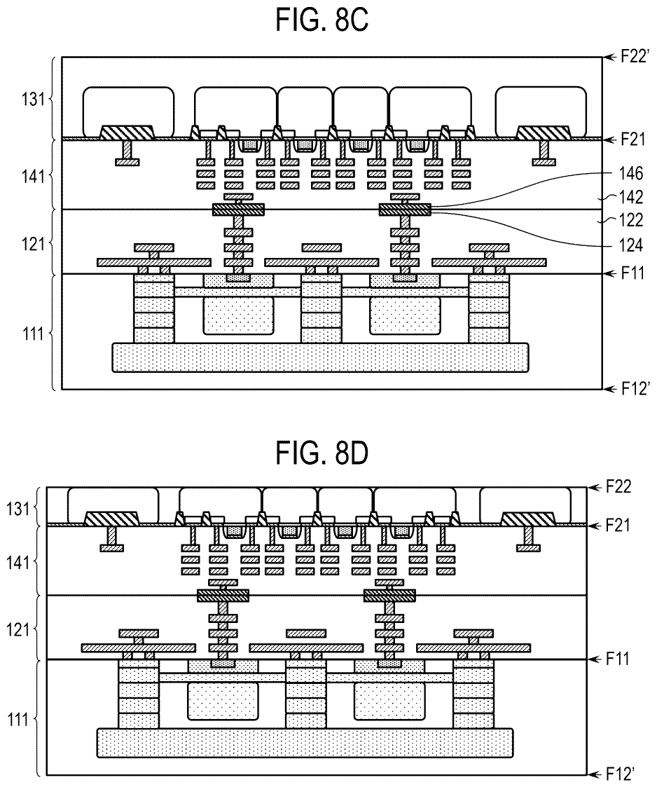

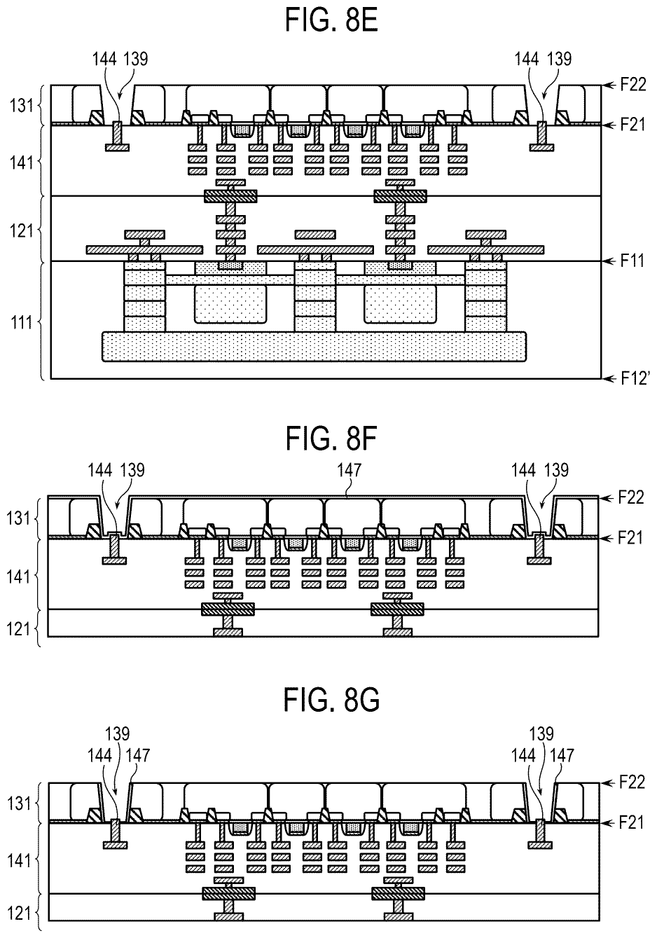

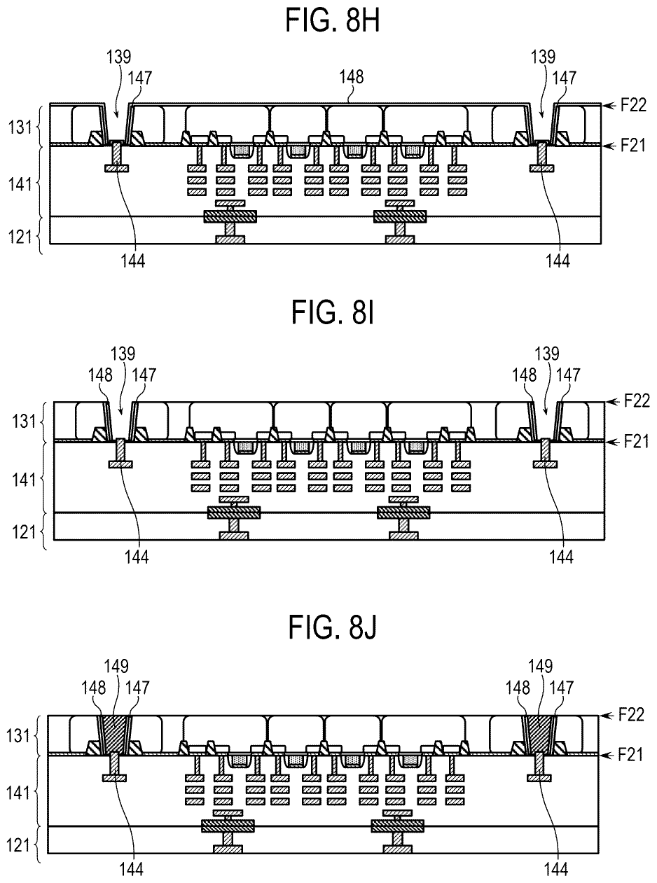

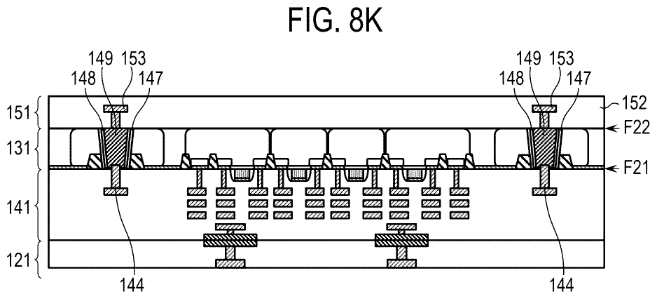

Next, a method of manufacturing the photoelectric conversion device according to the present embodiment will be described with reference to FIG. 8A to FIG. 8K. FIG. 8A to FIG. 8K are cross-sectional views illustrating a method of manufacturing the photoelectric conversion device according to the present embodiment.

First, a semiconductor layer (semiconductor substrate) 111 having a first face F11 and a second face F12′ is prepared, and at least photoelectric conversion elements 22 among the constituent elements of a plurality of pixels 12 are formed in the side of the first face F11 of the semiconductor layer 111. Next, an interconnection structure layer 121 in which one or a plurality of interconnection layers including interconnections 123 and 124 is provided in an insulating layer 122 is formed over the first face F11 of the semiconductor layer 111. Thus, a sensor substrate 110 including the semiconductor layer 111 and the interconnection structure layer 121 is formed (FIG. 8A).

In addition, a semiconductor layer (semiconductor substrate) 131 having a first face F21 and a second face F22′ is prepared separately from the sensor substrate 110, and other constituent elements of the pixels 12 and elements constituting the peripheral circuit block are formed in the side of the first face F21 of the semiconductor layer 131. Next, an interconnection structure layer 141 in which one or a plurality of interconnection layers including contact plugs 143 and 144 and interconnections 145 and 146 is provided in the insulating layer 142 is formed over the first face F21 of the semiconductor layer 131. Thus, a circuit substrate 130 including the semiconductor layer 131 and the interconnection structure layer 141 is formed (FIG. 8B).

Next, the sensor substrate 110 and the circuit substrate 130 thus prepared are joined so that the first face F11 that is a front face side of the semiconductor layer 111 and the first face F21 that is a front surface side of the semiconductor layer 131 face each other, that is, in a face-to-face manner (FIG. 8C). At this time, the sensor substrate 110 and the circuit substrate 130 may be electrically connected to each other by forming a metal-metal bonding between the uppermost-level metal interconnection (interconnection 124) of the interconnection structure layer 121 and the uppermost-level metal interconnection (interconnection 146) of the interconnection structure layer 141.

Next, the semiconductor layer 131 of the circuit substrate 130 is thinned by polishing back from the side of the second face F22′ by, e.g., a chemical mechanical polishing (CMP) method. A surface newly formed by polishing back the semiconductor layer 131 is a second face F22 of the semiconductor layer 131 (FIG. 8D). The thinner the semiconductor layer 131 of the circuit substrate 130, the easier it is to electrically isolate wells of the same conductivity type from each other to improve the degree of freedom in design, so it is preferable to process it as thin as possible. The impurity concentration in the depth direction of the well may be distributed from the viewpoint of reducing the influence of leakage current due to defects remaining in the vicinity of the second face F22 after thinning the semiconductor layer 131.

Next, a through-hole 139 reaching the contact plug 144 is formed in the semiconductor layer 131 by photolithography and dry etching (FIG. 8E). At this time, the through-hole 139 preferably has a tapered shape in which the opening width on the side of the second face F22 is larger than the opening width on the side of the first face F21. By forming the through-hole 139 in such a shape, the film formation in the through-hole 139 becomes easy, and the uniformity of the film thickness of the fixed charge containing layer 147 and the insulating layer 148 in the through-hole 139 and the burying characteristics of the through-hole electrode 149 may be improved. In addition, from the viewpoint of suppressing a dark current caused by etching damage, it is preferable to perform chemical dry etching to remove surface damage of the through-hole 139. The opening width of the through-hole 139 on the side of the first face F21 is preferably formed to be sufficiently larger than the diameter of the contact plug 144. As a result, the contact area between the through-electrode 149 and the contact plug 144 may be increased, the contact failure due to the manufacturing variation may be suppressed, and the conduction failure may be reduced.

Next, a film having fixed charges is deposited over the entire surface on the side of the second face F22 including the inside of the through-hole 139 by, e.g., an atomic layer deposition (ALD) method to form a fixed charge containing layer 147 (FIG. 8F). The fixed charge containing layer 147 may be made of, e.g., hafnium oxide, zirconium oxide, aluminum oxide, titanium oxide, tantalum oxide, or the like. In the following drawings, the semiconductor layer 111 and a part of the interconnection structure layer 121 are omitted for simplification.

Next, the fixed charge containing layer 147 is etched back from the side of the second face F22 by anisotropic etching, and the fixed charge containing layer 147 on the surface of the second face F22 and the bottom of the through-hole 139 is selectively removed. Thus, the fixed charge containing layer 147 on the surface of the second face F22 is removed and the contact plug 144 is exposed again at the bottom of the through-hole 139 while leaving the fixed charge containing layer 147 on the side wall of the through-hole 139 (FIG. 8G).

Next, an insulating material such as SiO, SiN, SiON, SiC, or SiCN is deposited over the entire surface on the side of the second face F22 including the inside of the through-hole 139 in which the fixed charge containing layer 147 is provided by, for example, a chemical vapor deposition (CVD) method to form an insulating layer 148 (FIG. 8H). The insulating layer 148 may be formed such that the film thickness of the insulating layer 148 on the side of the first face F21 is thicker than the film thickness of the insulating layer 148 on the side of the second face F22. By doing so, in a process to be described later, when a conductive material is deposited in the through-hole 139, a gap is less likely to be formed in the through-hole 139, and thus an effect that the electric resistance value is less likely to vary may be obtained.

Next, the insulating layer 148 is etched back from the side of the second face F22 by anisotropic etching, and the insulating layer 148 on the surface of the second face F22 and the bottom of the through-hole 139 is selectively removed. Thus, the insulating layer 148 on the surface of the second face F22 is removed and the contact plug 144 is exposed again at the bottom of the through-hole 139 while leaving the insulating layer 148 on the side wall of the through-hole 139 in which the fixed charge containing layer 147 is provided (FIG. 8I).

Next, a conductive material such as tungsten, aluminum, or copper is deposited over the entire surface on the side of the second face F22 including the inside of the through-hole 139 by, for example, a CVD method, a sol-gel method, or the like. Thereafter, the conductive material on the second face F22 is removed by anisotropic etching or CMP method so that the conductive material remains only in the through-hole 139. Thereby, the through-electrode 149 made of the conductive material buried in the through-hole 139 in which the stacked film of the fixed charge containing layer 147 and the insulating layer 148 is provided on the side surface portion is formed (FIG. 8J).

Next, an interconnection structure layer 151 including the insulating layer 152 and the interconnection 153 electrically connected to the contact plug 144 via the through-electrode 149 is formed over the second face F22 of the semiconductor layer 131 in which the through-electrode 149 is buried (FIG. 8K). At this time, at least a portion of the insulating layer 152 in contact with the second face F22 of the semiconductor layer 131 is formed of an insulating material containing silicon such as SiO, SiN, SiON, SiC, or SiCN.

Thereafter, the semiconductor layer 111 is thinned by polishing back the semiconductor layer 111 of the sensor substrate 110 from the side of the second face F12′ by, for example, CMP method from the side of the second face F12′ until reaching the p-type semiconductor region 117. Then, the optical structure layer 181 is formed over the second face F12 of the semiconductor layer 111 formed by thinning to complete the photoelectric conversion device according to the present embodiment (see FIG. 6).

As described above, in the present embodiment, the fixed charge containing layer is arranged between the sidewall of the through-hole penetrating the semiconductor layer and the through-electrode, and the insulating layer made of the insulating material containing silicon not containing the fixed charge is provided in contact with the back surface of the semiconductor layer. Therefore, according to the present embodiment, it is possible to effectively reduce noise caused by damage at the time of forming the through-hole and the through-electrode.

### Second Embodiment

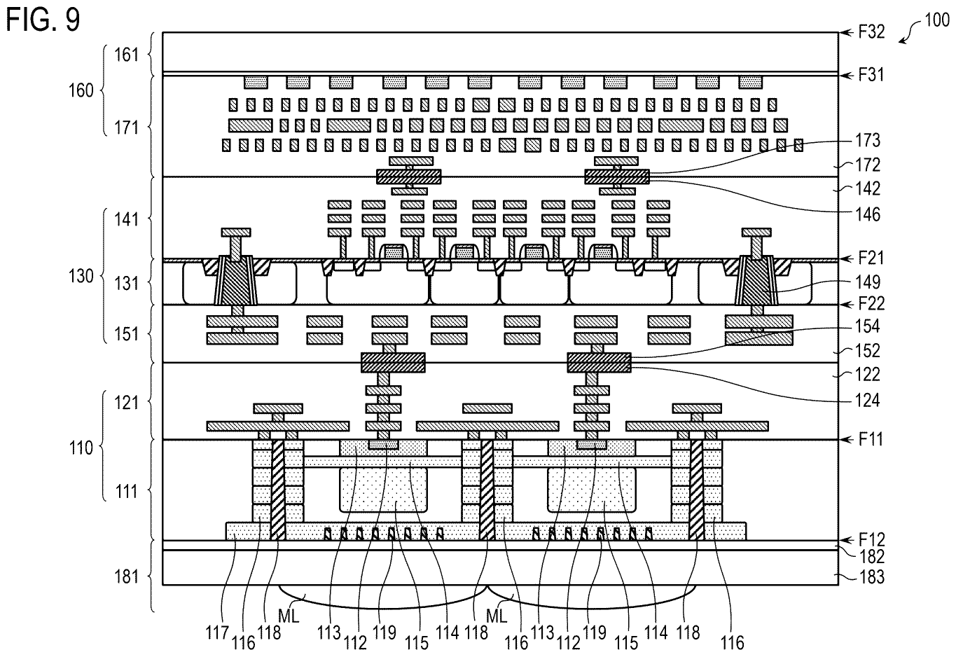

A photoelectric conversion device according to a second embodiment will be described with reference to FIG. 9. FIG. 9 is a schematic cross-sectional view illustrating a configuration example of the photoelectric conversion device according to the present embodiment. The same components as those of the photoelectric conversion device according to the first embodiment are denoted by the same reference numerals, and description thereof will be omitted or simplified.

As illustrated in FIG. 9, the photoelectric conversion device 100 according to the present embodiment is formed by stacking a sensor substrate 110, a circuit substrate 130, and a circuit substrate 160. The sensor substrate 110 includes a semiconductor layer 111 having a first face F11 and a second face F12 opposite to the first face F11, and an interconnection structure layer 121 provided on the side of the first face F11 of the semiconductor layer 111. The circuit substrate 130 includes a semiconductor layer 131 having a first face F21 and a second face F22 opposite to the first face F21, an interconnection structure layer 141 provided on the side of the first face F21 of the semiconductor layer 131, and an interconnection structure layer 151 provided on the side of the second face F22 of the semiconductor layer 131. The circuit substrate 160 includes a semiconductor layer 161 having a first face F31 and a second face F32 opposite to the first face F31, and an interconnection structure layer 171 provided on the side of the first face F31 of the semiconductor layer 161. The interconnection structure layer 171 includes an insulating layer 172 and one or a plurality of interconnection layers arranged therein. The one or the plurality of interconnection layers includes the interconnection 173 formed of the uppermost-level interconnection layer that is most distant from the first face F31.

The sensor substrate 110 and the circuit substrate 130 are bonded to each other in a face-to-back manner such that the side of the first face F11 of the semiconductor layer 111 on which the interconnection structure layer 121 is arranged faces the side of the second face F22 of the semiconductor layer 131 on which the interconnection structure layer 151 is arranged. That is, the bonding surface between the sensor substrate 110 and the circuit substrate 130 is formed by the interface between the interconnection structure layer 121 and the interconnection structure layer 151. The electrical connection between the sensor substrate 110 and the circuit substrate 130 may be formed by metal-metal bonding between the uppermost-level metal interconnection (interconnection 124) constituting the interconnection structure layer 121 and the uppermost-level metal interconnection (interconnection 154) constituting the interconnection structure layer 151.

The circuit substrate 130 and the circuit substrate 160 are bonded to each other in a face-to-face manner such that the first face F21 of the semiconductor layer 131 on which the interconnection structure layer 141 is arranged faces the first face F31 of the semiconductor layer 161 on which the interconnection structure layer 171 is arranged. That is, the bonding surface between the circuit substrate 130 and the circuit substrate 160 is formed by the interface between the interconnection structure layer 141 and the interconnection structure layer 171. The electrical connection between the circuit substrate 130 and the circuit substrate 160 may be formed by metal-metal bonding between the uppermost-level metal interconnection (interconnection 146) constituting the interconnection structure layer 141 and the uppermost-level metal interconnection (interconnection 173) constituting the interconnection structure layer 171.

As described above, the photoelectric conversion device according to the present embodiment is a back illuminated photoelectric conversion device similar to that of the first embodiment. On the other hand, the photoelectric conversion device according to the present embodiment is different from the photoelectric conversion device according to the first embodiment in which the sensor substrate 110 and the circuit substrate 130 are bonded to each other in a face-to-face manner in that the sensor substrate 110 and the circuit substrate 130 are bonded to each other in a face-to-back manner. Since the distance from the light incident surface to the MOS transistor arranged in the semiconductor layer 131 may be increased by bonding the sensor substrate 110 and the circuit substrate 130 to each other in a face-to-back manner, it is possible to suppress the characteristic variation of the MOS transistor as compared with the first embodiment.

Also in the photoelectric conversion device according to the present embodiment, the through-electrode 149 may have a configuration similar to that of the first embodiment.

As described above, according to the present embodiment, as in the first embodiment, it is possible to effectively reduce noise caused by damage when forming the through-hole and the through-electrode.

### Third Embodiment

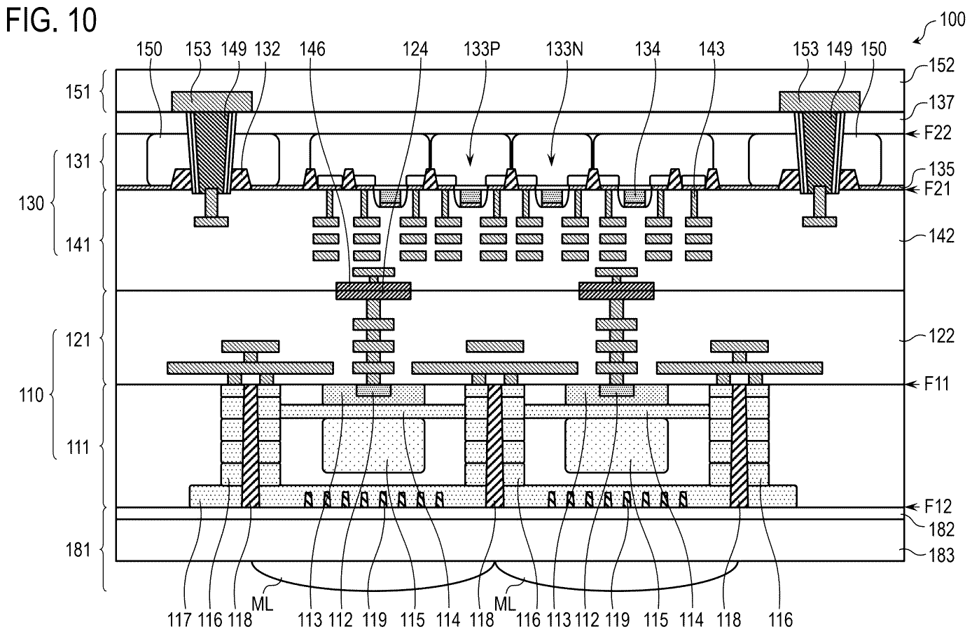

A photoelectric conversion device according to a third embodiment will be described with reference to FIG. 10. FIG. 10 is a schematic cross-sectional view illustrating a configuration example of the photoelectric conversion device according to the present embodiment. The same components as those of the photoelectric conversion device according to the first or second embodiment are denoted by the same reference numerals, and description thereof will be omitted or simplified.

The photoelectric conversion device according to the present embodiment is a back illuminated photoelectric conversion device similar to the first embodiment but differs from the photoelectric conversion device according to the first embodiment in the configuration of the portion where the through-electrode 149 is arranged. That is, as illustrated in FIG. 10, the photoelectric conversion device according to the present embodiment further includes an insulating layer 137 provided between the second face F22 of the semiconductor layer 131 and the interconnection structure layer 151, and the through-electrode 149 is provided in the through-hole penetrating through the semiconductor layer 131 and the insulating layer 137. As a constituent material of the insulating layer 137, an insulating material containing silicon such as, e.g., SiO, SiN, SiON, SiC, or SiCN may be preferably used as in the case of the insulating layer 152 described above.

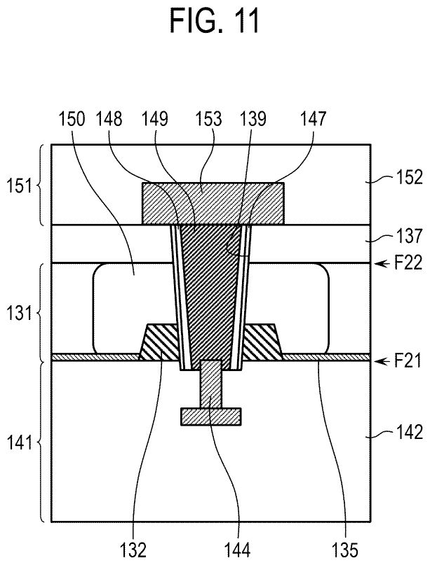

FIG. 11 is an enlarged cross-sectional view of a portion where the through-electrode 149 is provided. The insulating layer 137 is provided over the second face F22 of the semiconductor layer 131. A through-hole 139 penetrating the insulating layer 137 and the semiconductor layer 131 is provided. The fixed charge containing layer 147, the insulating layer 148, and the through-electrode 149 are provided in the through-hole 139. The fixed charge containing layer 147 is provided so as to be in contact with the inner surface of the through-hole 139. The insulating layer is provided along the inner surface of the through-hole 139 in which the fixed charge containing layer 147 is provided. The through-electrode 149 is provided so as to fill the through-hole 139 in which the fixed charge containing layer 147 and the insulating layer 148 are provided.

With this configuration, the through-electrode 149 is arranged not only in the semiconductor layer 131 but also in the insulating layer 137. Thus, the through-electrode 149 may also serve as a contact plug for electrically connecting to the interconnection 153 arranged in the insulating layer 152, and the manufacturing process may be simplified. In addition, the contact failure between the through-electrode 149 and the interconnection 153 may be reduced.

In the case of the above configuration, the through-hole 139, the fixed charge containing layer 147, the insulating layer 148, and the through-electrode 149 are formed after the insulating layer 137 is formed over the semiconductor layer 131. That is, the second face F22 of the semiconductor layer 131 may be protected from damage during anisotropic etching when forming the fixed charge containing layer 147 and the insulating layer 148 and during CMP when forming the through-electrode 149. Accordingly, it is possible to suppress a dark current due to damage introduced to the second face F22 of the semiconductor layer 131.

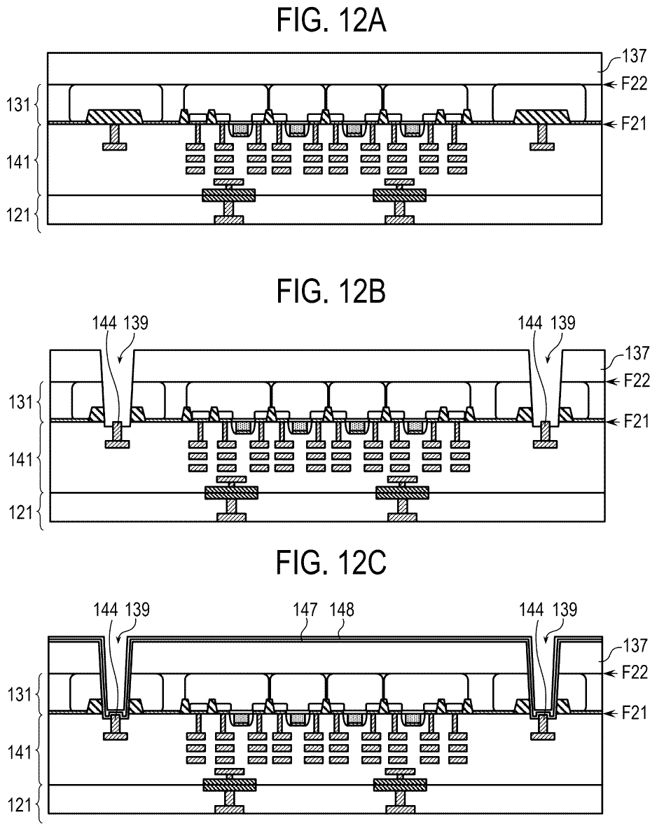

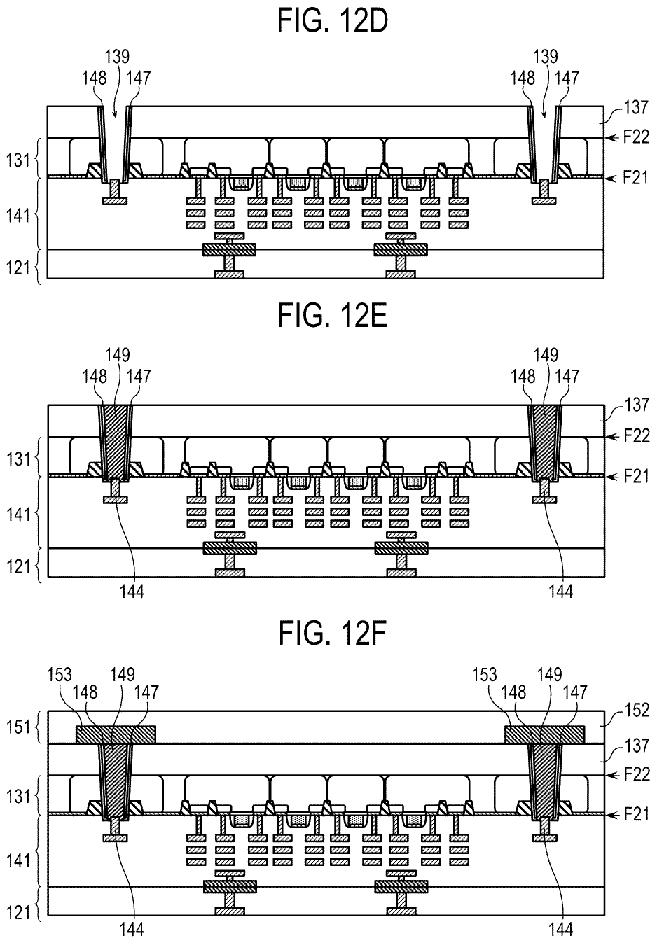

Next, a method of manufacturing the photoelectric conversion device according to the present embodiment will be described with reference to FIG. 12A to FIG. 12F. FIG. 12A to FIG. 12F are cross-sectional views illustrating a method of manufacturing the photoelectric conversion device according to the present embodiment.

First, in the same manner as in the manufacturing method of the first embodiment illustrated in FIG. 8A to FIG. 8D, the sensor substrate 110 and the circuit substrate 130 are bonded to each other, and the semiconductor layer 131 is thinned from the side of the second face F22′.

Next, an insulating material such as SiO, SiN, SiON, SiC, SiCN, or the like is deposited by, e.g., a CVD method or a sol-gel method over the second face F22 of the semiconductor layer 131 formed by thinning to form an insulating layer 137 (FIG. 12A). At this time, the insulating layer 137 is set to a film thickness such that the second face F22 of the semiconductor layer 131 is not exposed at the time of forming the interconnection 153 in consideration of a decrease in film thickness due to processing at the time of forming the through-electrode 149, the interconnection 153, and the like described later.

Next, a through-hole 139 reaching the contact plug 144 is formed in the insulating layer 137 and the semiconductor layer 131 by photolithography and dry etching (FIG. 12B).

Next, a fixed charge containing layer 147 and an insulating layer 148 are deposited over the entire surface on the side of the second face F22 including over the insulating layer 137 and inside the through-hole 139 by, for example, a CVD method, an ALD method, a sol-gel method, or the like (FIG. 12C).

Next, the insulating layer 148 and the fixed charge containing layer 147 are etched back from the side of the second face F22 by anisotropic etching, and the insulating layer 148 and the fixed charge containing layer 147 over the surface of the insulating layer 137 and the bottom of the through-hole 139 are selectively removed. Thereby, the insulating layer 148 and the fixed charge containing layer 147 over the surface of the insulating layer 137 are removed and the contact plug 144 is exposed again at the bottom portion of the through-hole 139 while leaving the fixed charge containing layer 147 and the insulating layer 148 in the side wall portion of the through-hole 139 (FIG. 12D).

The etching back of the insulating layer 148 and the fixed charge containing layer 147 may be performed every time the fixed charge containing layer 147 and the insulating layer 148 are deposited as in the first embodiment. In the first embodiment, the insulating layer 148 and the fixed charge containing layer 147 may be continuously etched back as in the present embodiment.

Next, a conductive material is deposited over the entire surface on the side of the second face F22 including over the insulating layer 137 and inside the through-hole 139 by, e.g., a CVD method, a sol-gel method, or the like. Thereafter, the conductive material over the insulating layer 137 is removed by anisotropic etching or a CMP method so that the conductive material remains only in the through-hole 139. Thereby, the through-electrode 149 made of a conductive material buried in the through-hole 139 in which the stacked film of the fixed charge containing layer 147 and the insulating layer 148 is provided on the side surface is formed (FIG. 12E).

Next, an interconnection structure layer 151 including an interconnection 153 electrically connected to the contact plug 144 via the through-electrode 149 and an insulating layer 152 is formed over the insulating layer 137 in which the through-electrode 149 is buried (FIG. 12F).

Thereafter, the semiconductor layer 111 is thinned by polishing back the semiconductor layer 111 of the sensor substrate 110 from the side of the second face F12′ by, e.g., a CMP method from the side of the second face F12′ until reaching the p-type semiconductor region 117. Then, an optical structure layer 181 is formed over the second face F12 of the semiconductor layer 111 formed by thinning to complete the photoelectric conversion device according to the present embodiment (see FIG. 10).

As described above, according to the present embodiment, as in the first embodiment, it is possible to effectively reduce noise caused by damage when forming the through-hole and the through-electrode.

### Fourth Embodiment

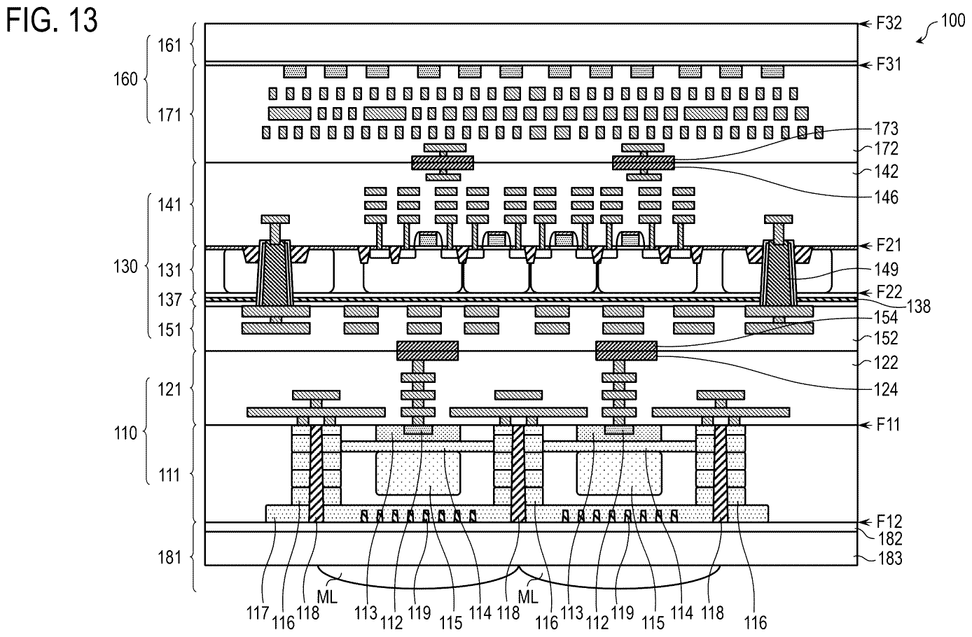

A photoelectric conversion device according to a fourth embodiment will be described with reference to FIG. 13. FIG. 13 is a schematic cross-sectional view illustrating a configuration example of the photoelectric conversion device according to the present embodiment. The same components as those of the photoelectric conversion devices according to the first to third embodiments are denoted by the same reference numerals, and description thereof will be omitted or simplified.

As illustrated in FIG. 13, the photoelectric conversion device 100 according to the present embodiment is formed by stacking a sensor substrate 110, a circuit substrate 130, and a circuit substrate 160. The sensor substrate 110 includes a semiconductor layer 111 having a first face F11 and a second face F12 opposite to the first face F11, and an interconnection structure layer 121 provided on the side of the first face F11 of the semiconductor layer 111. The circuit substrate 130 includes a semiconductor layer 131 having a first face F21 and a second face F22 opposite to the first face F21, an interconnection structure layer 141 provided on the side of the first face F21 of the semiconductor layer 131, and an interconnection structure layer 151 provided on the side of the second face F22 of the semiconductor layer 131. The circuit substrate 160 includes a semiconductor layer 161 having a first face F31 and a second face F32 opposite to the first face F31, and an interconnection structure layer 171 provided on the side of the first face F31 of the semiconductor layer 161. The interconnection structure layer 171 includes an insulating layer 172 and one or a plurality of interconnection layers arranged therein. The one or the plurality of interconnection layers includes the interconnection 173 formed of the uppermost-level interconnection layer that is most distant from the first face F31.

The sensor substrate 110 and the circuit substrate 130 are bonded to each other in a face-to-back manner such that the side of the first face F11 of the semiconductor layer 111 on which the interconnection structure layer 121 is arranged faces the side of the second face F22 of the semiconductor layer 131 on which the interconnection structure layer 151 is arranged. That is, the bonding surface between the sensor substrate 110 and the circuit substrate 130 is formed by the interface between the interconnection structure layer 121 and the interconnection structure layer 151. The electrical connection between the sensor substrate 110 and the circuit substrate 130 may be formed by metal-metal bonding between the uppermost-level metal interconnection (interconnection 124) constituting the interconnection structure layer 121 and the uppermost-level metal interconnection (interconnection 154) constituting the interconnection structure layer 151.

The circuit substrate 130 and the circuit substrate 160 are bonded to each other in a face-to-face manner such that the side of the first face F21 of the semiconductor layer 131 on which the interconnection structure layer 141 is arranged faces the side of the first face F31 of the semiconductor layer 161 on which the interconnection structure layer 171 is arranged. That is, the bonding surface between the circuit substrate 130 and the circuit substrate 160 is formed by the interface between the interconnection structure layer 141 and the interconnection structure layer 171. The electrical connection between the circuit substrate 130 and the circuit substrate 160 may be formed by metal-metal bonding between the uppermost-level metal interconnection (interconnection 146) constituting the interconnection structure layer 141 and the uppermost-level metal interconnection (interconnection 173) constituting the interconnection structure layer 171.

As described above, the photoelectric conversion device according to the present embodiment is a back illuminated photoelectric conversion device similar to that of the first embodiment. On the other hand, the photoelectric conversion device according to the present embodiment is different from the photoelectric conversion device according to the first embodiment in which the sensor substrate 110 and the circuit substrate 130 are bonded to each other in a face-to-face manner in that the sensor substrate 110 and the circuit substrate 130 are bonded to each other in a face-to-back manner. By bonding the sensor substrate 110 and the circuit substrate 130 to each other in a face-to-back manner, it is possible to increase the distance from the light incident surface to the MOS transistor arranged in the semiconductor layer 131, and it is possible to make the characteristic variation of the MOS transistor less likely to occur as compared with the first embodiment.

In the present embodiment, the through-electrode 149 has the same configuration as that of the third embodiment, but the insulating layer 137 arranged between the semiconductor layer 131 and the interconnection structure layer 151 has a multilayer film structure including an insulating layer 138 having a refractive index larger than that of the insulating layer 152. For example, when the insulating layer 152 is formed of a SiO film, the insulating layer 138 may be formed of a SiN film. When the insulating layer 137 has such a multilayer film structure, it is possible to more effectively prevent light incident from the light incident surface side from being incident on the semiconductor layer 131 side.

As described above, according to the present embodiment, as in the first embodiment, it is possible to effectively reduce noise caused by damage when forming the through-hole and the through-electrode.

### Fifth Embodiment

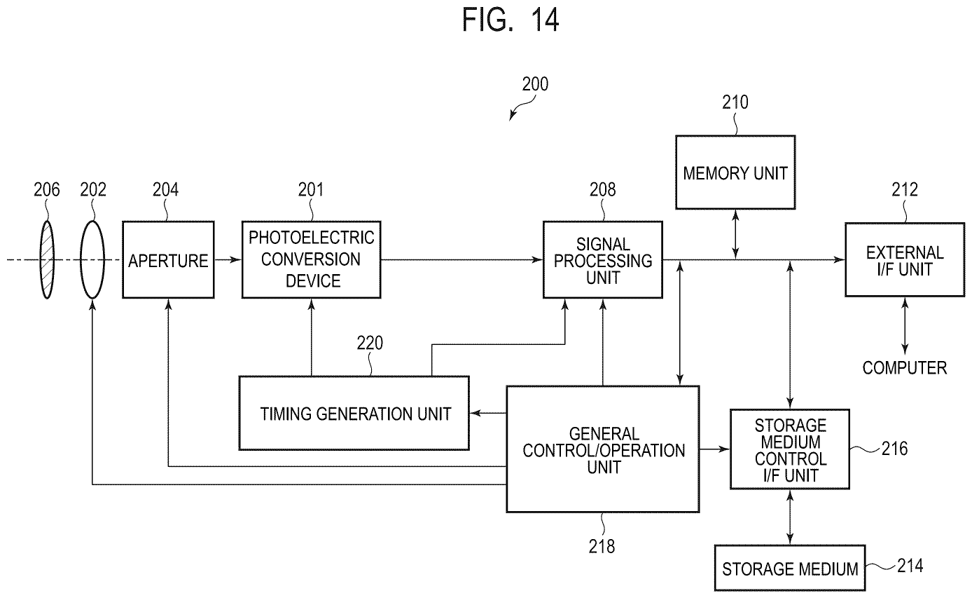

A photodetection system according to a fifth embodiment will be described with reference to FIG. 14. FIG. 14 is a block diagram illustrating a schematic configuration of a photodetection system according to the present embodiment. In the present embodiment, a photodetection sensor to which the photoelectric conversion device 100 according to any one of the first to fourth embodiments is applied will be described.

The photoelectric conversion device 100 described in the first to fourth embodiments may be applied to various photodetection systems. Examples of applicable photodetection systems include imaging systems such as digital still cameras, digital camcorders, surveillance cameras, copying machines, facsimiles, mobile phones, on-vehicle cameras, observation satellites, and the like. A camera module including an optical system such as a lens and an imaging device is also included in the photodetection system. FIG. 14 exemplifies a block diagram of a digital still camera as one of these.

The photodetection system 200 illustrated in FIG. 14 includes a photoelectric conversion device 201, a lens 202 that forms an optical image of an object on the photoelectric conversion device 201, an aperture 204 that changes the amount of light passing through the lens 202, and a barrier 206 that protects the lens 202. The lens 202 and the aperture 204 constitute an optical system that focuses light onto the photoelectric conversion device 201. The photoelectric conversion device 201 is the photoelectric conversion device 100 described in any one of the first to fourth embodiments and converts the optical image formed by the lens 202 into image data.

The photodetection system 200 further includes a signal processing unit 208 that processes an output signal output from the photoelectric conversion device 201. The signal processing unit 208 generates image data from the digital signal output from the photoelectric conversion device 201. Further, the signal processing unit 208 performs various corrections and compressions as necessary and outputs the processed image data. The photoelectric conversion device 201 may include an AD conversion unit that generates a digital signal to be processed by the signal processing unit 208. The AD conversion unit may be formed on a semiconductor layer (semiconductor substrate) on which the photoelectric conversion element of the photoelectric conversion device 201 is formed or may be formed on a semiconductor layer different from the semiconductor layer on which the photoelectric conversion element of the photoelectric conversion device 201 is formed. The signal processing unit 208 may be formed on the same semiconductor layer as the photoelectric conversion device 201.

The photodetection system 200 further includes a memory unit 210 for temporarily storing image data and an external interface unit (external I/F unit) 212 for communicating with an external computer or the like. Further, the photodetection system 200 includes a storage medium 214 such as a semiconductor memory for performing storing or reading out of imaging data, and a storage medium control interface unit (storage medium control I/F unit) 216 for performing storing on or reading out from the storage medium 214. The storage medium 214 may be built in the photodetection system 200 or may be detachable. Communication between the storage medium control I/F unit 216 and the storage medium 214 and communication from the external I/F unit 212 may be performed wirelessly.

The photodetection system 200 further includes a general control/operation unit 218 that performs various calculations and controls the entire digital still camera, and a timing generation unit 220 that outputs various timing signals to the photoelectric conversion device 201 and the signal processing unit 208. Here, the timing signal or the like may be input from the outside, and the photodetection system 200 may include at least the photoelectric conversion device 201 and the signal processing unit 208 that processes the output signal output from the photoelectric conversion device 201. The timing generation unit 220 may be mounted on the photoelectric conversion device 201. Further, the general control/operation unit 218 and the timing generation unit 220 may be configured to perform a part or all of the control functions of the photoelectric conversion device 201.

The photoelectric conversion device 201 outputs an imaging signal to the signal processing unit 208. The signal processing unit 208 performs predetermined signal processing on the imaging signal output from the photoelectric conversion device 201 and outputs image data. The signal processing unit 208 generates an image using the imaging signal. The signal processing unit 208 may be configured to perform distance measurement calculation on the signal output from the photoelectric conversion device 201.

As described above, according to the present embodiment, by configuring the photodetection system using the photoelectric conversion device according to any one of the first to fourth embodiments, it is possible to realize a photodetection system capable of acquiring a higher quality image.

### Sixth Embodiment

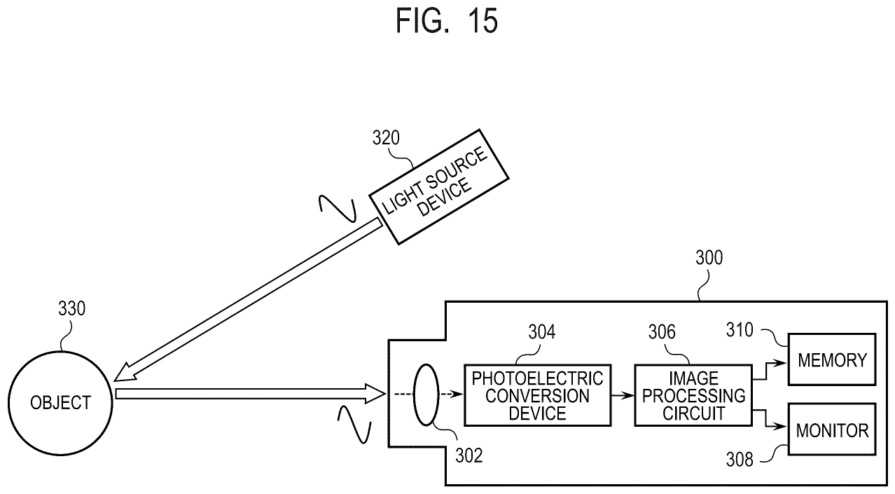

A range image sensor according to a sixth embodiment will be described with reference to FIG. 15. FIG. 15 is a block diagram illustrating a schematic configuration of a range image sensor according to the present embodiment. In the present embodiment, a range image sensor will be described as an example of a photodetection system to which the photoelectric conversion device 100 according to any one of the first to fourth embodiments is applied.

As illustrated in FIG. 15, the range image sensor 300 according to the present embodiment may include an optical system 302, a photoelectric conversion device 304, an image processing circuit 306, a monitor 308, and a memory 310. The range image sensor 300 receives light (modulated light or pulsed light) emitted from a light source device 320 toward an object 330 and reflected on the surface of the object 330 and acquires a distance image corresponding to the distance to the object 330.

The optical system 302 includes one or a plurality of lenses and has a function of forming an image of image light (incident light) from the object 330 on a light receiving surface (sensor unit) of the photoelectric conversion device 304.

The photoelectric conversion device 304 is the photoelectric conversion device 100 described in any one of the first to fourth embodiments and has a function of generating a distance signal indicating a distance to the object 330 based on image light from the object 330 and supplying the generated distance signal to the image processing circuit 306.

The image processing circuit 306 has a function of performing image processing for constructing a distance image based on the distance signal supplied from the photoelectric conversion device 304.

The monitor 308 has a function of displaying a distance image (image data) obtained by image processing in the image processing circuit 306. The memory 310 has a function of storing (recording) a distance image (image data) obtained by image processing in the image processing circuit 306.

As described above, according to the present embodiment, by configuring the range image sensor using the photoelectric conversion devices according to any one of the first to fourth embodiments, it is possible to realize a range image sensor capable of acquiring a range image including more accurate range information in conjunction with improvement in characteristics of the pixels 12.

### Seventh Embodiment

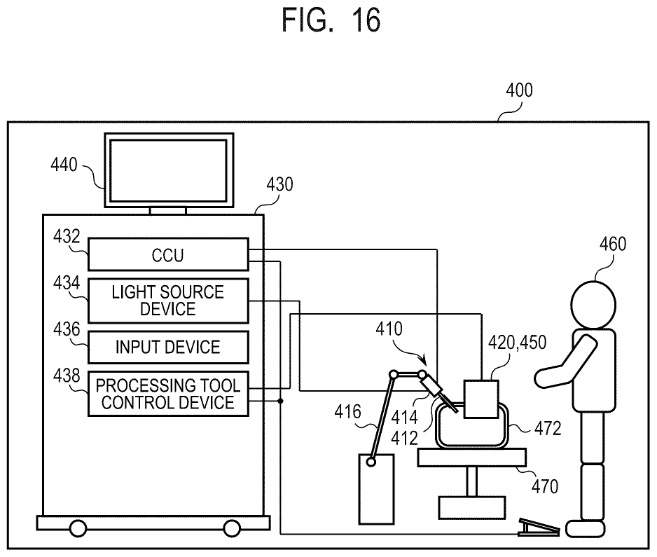

An endoscopic surgical system according to a seventh embodiment will be described with reference to FIG. 16. FIG. 16 is a schematic diagram illustrating a configuration example of the endoscopic surgical system according to the present embodiment. In the present embodiment, an endoscopic surgical system will be described as an example of a photodetection system to which the photoelectric conversion device 100 according to any one of the first to fourth embodiments is applied.

FIG. 16 illustrates a state in which an operator (surgeon) 460 performs surgery on a patient 472 on a patient bed 470 using an endoscopic surgical system 400.

As illustrated in FIG. 16, the endoscopic surgical system 400 according to the present embodiment may include an endoscope 410, a surgical tool 420, and a cart 430 on which various devices for endoscopic surgery are mounted. A camera control unit (CCU) 432, a light source device 434, an input device 436, a processing tool control device 438, a display device 440, and the like may be mounted on the cart 430.

The endoscope 410 includes a lens barrel 412 in which an area of a predetermined length from the tip is inserted into a body cavity of the patient 472, and a camera head 414 connected to the base end of the lens barrel 412. Although FIG. 16 illustrates an endoscope 410 configured as a so-called rigid mirror having a rigid lens barrel 412, the endoscope 410 may be configured as a so-called flexible mirror having a flexible lens barrel. The endoscope 410 is held in a movable state by an arm 416.

The tip of the lens barrel 412 is provided with an opening into which an objective lens is fitted. A light source device 434 is connected to the endoscope 410, and light generated by the light source device 434 is guided to the tip of the lens barrel 412 by a light guide extended inside the lens barrel and is irradiated toward an observation target in the body cavity of the patient 472 through the objective lens. Note that the endoscope 410 may be a direct-viewing mirror, an oblique-viewing mirror, or a side-viewing mirror.

An optical system and a photoelectric conversion device (not illustrated) are provided inside the camera head 414, and reflected light (observation light) from the observation target is focused on the photoelectric conversion device by the optical system. The photoelectric conversion device photoelectrically converts the observation light and generates an electrical signal corresponding to the observation light, that is, an image signal corresponding to the observation image. As the photoelectric conversion device, the photoelectric conversion device 100 described in any one of the first to fourth embodiments may be used. The image signal is transmitted to the CCU 432 as RAW data.

The CCU 432 may be configured by a central processing unit (CPU), a graphics processing unit (GPU), or the like, and integrally controls operations of the endoscope 410 and the display device 440. Further, the CCU 432 receives an image signal from the camera head 414 and performs various types of image processing for displaying an image based on the image signal, such as development processing (demosaic processing), on the image signal.

The display device 440 displays an image based on the image signal subjected to the image processing by the CCU 432 under the control of the CCU 432.

The light source device 434 may be configured by, for example, a light source such as a light emitting diode (LED), and supplies irradiation light to the endoscope 410 when photographing a surgical part or the like.

The input device 436 is an input interface to the endoscopic surgical system 400. The user may input various kinds of information and input instructions to the endoscopic surgical system 400 via the input device 436.

The processing tool control device 438 controls the driving of the energy processing tool 450 for tissue ablation, incision, blood vessel sealing, or the like.

The light source device 434 that supplies irradiation light to the endoscope 410 when imaging the surgical part may be configured by, for example, a white light source configured by an LED, a laser light source, or a combination thereof. When the white light source is configured by a combination of the RGB laser light sources, since the output intensity and the output timing of each color (each wavelength) may be controlled with high accuracy, the white balance of the captured image may be adjusted in the light source device 434. In addition, in this case, it is also possible to capture an image corresponding to each of RGB in a time division manner by irradiating the observation target with laser light from each of the RGB laser light sources in a time division manner and controlling driving of the imaging element of the camera head 414 in synchronization with the irradiation timing. According to this method, a color image may be obtained without providing a color filter in the image sensor.

Further, the driving of the light source device 434 may be controlled so as to change the intensity of light to be output every predetermined time. By controlling the driving of the image sensor of the camera head 414 in synchronization with the timing of the change of the intensity of the light to acquire an image in a time-division manner and compositing the image, it is possible to generate an image having a high dynamic range free from so-called blacked up shadows and blown out highlights.

The light source device 434 may be configured to be capable of supplying light in a predetermined wavelength band corresponding to special light observation. In the special light observation, for example, wavelength dependency of absorption of light in body tissue is utilized. Specifically, a predetermined tissue such as a blood vessel in the superficial layer of a mucous membrane is photographed with high contrast by irradiating light in a narrow band as compared with irradiation light (that is, white light) at the time of normal observation. Alternatively, in the special light observation, fluorescence observation in which an image is obtained by fluorescence generated by irradiation with excitation light may be performed. In the fluorescence observation, a body tissue is irradiated with excitation light to observe fluorescence from the body tissue, or a body tissue is locally injected with a reagent such as indocyanine green (ICG), and the body tissue is irradiated with excitation light corresponding to a fluorescence wavelength of the reagent to obtain a fluorescence image. The light source device 434 may be configured to be capable of supplying narrowband light and/or excitation light corresponding to such special light observation.

As described above, according to the present embodiment, by configuring the endoscopic surgical system using the photoelectric conversion devices according to any one of the first to fourth embodiments, it is possible to realize an endoscopic surgical system capable of acquiring a better quality image.

### Eighth Embodiment

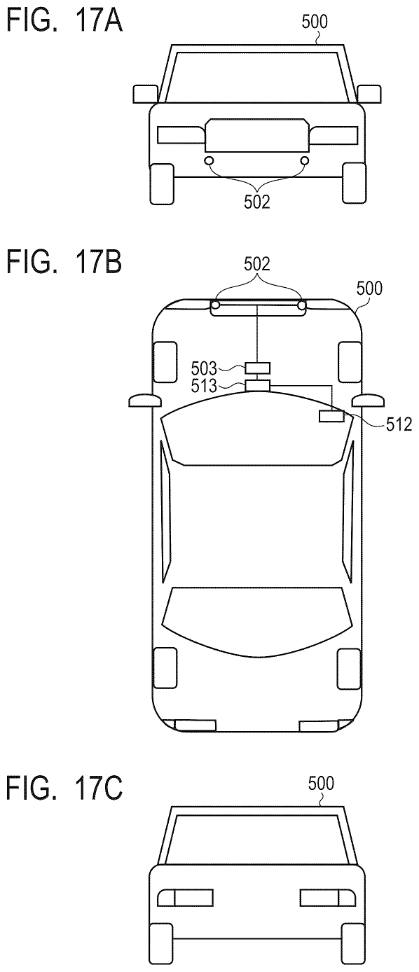

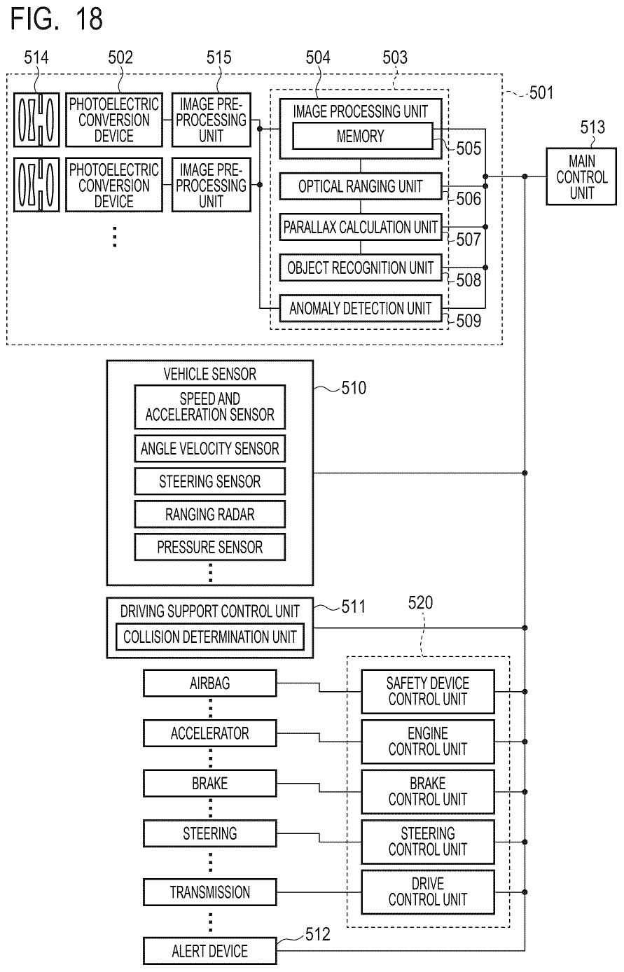

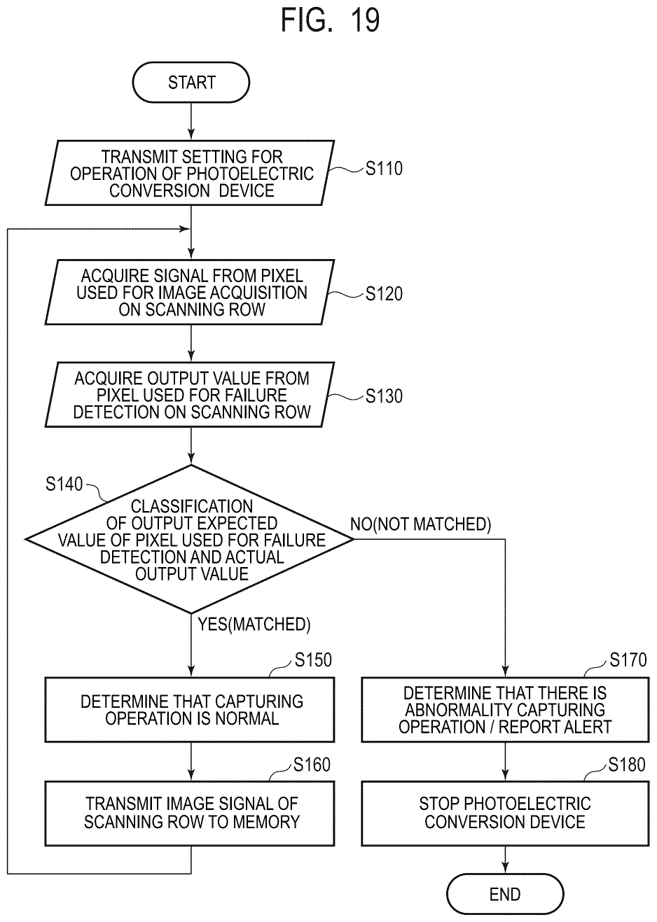

A photodetection system and a movable object according to an eighth embodiment will be described with reference to FIG. 17A to FIG. 19. FIG. 17A to FIG. 17C are schematic diagrams illustrating a configuration example of a movable object according to the present embodiment. FIG. 18 is a block diagram illustrating a schematic configuration of a photodetection system according to the present embodiment. FIG. 19 is a flowchart illustrating an operation of the photodetection system according to the present embodiment. In the present embodiment, an application example to an on-vehicle camera will be described as a photodetection system to which the photoelectric conversion device 100 according to any one of the first to fourth embodiments is applied.

FIG. 17A to FIG. 17C are schematic diagrams illustrating a configuration example of a movable object (vehicle system) according to the present embodiment. FIG. 17A to FIG. 17C illustrate a configuration of a vehicle 500 (automobile) as an example of a vehicle system incorporating a photodetection system to which the photoelectric conversion devices according to any one of the first to fourth embodiments is applied. FIG. 17A is a schematic front view of the vehicle 500, FIG. 17B is a schematic plan view of the vehicle 500, and FIG. 17C is a schematic rear view of the vehicle 500. The vehicle 500 includes a pair of photoelectric conversion devices 502 on a front face thereof. Here, the photoelectric conversion devices 502 are the photoelectric conversion device 100 described in any one of the first to fourth embodiments. The vehicle 500 includes an integrated circuit 503, an alert device 512, and a main control unit 513.

FIG. 18 is a block diagram illustrating a configuration example of the photodetection system 501 mounted on the vehicle 500. The photodetection system 501 includes photoelectric conversion devices 502, image preprocessing units 515, an integrated circuit 503, and optical systems 514. The photoelectric conversion device 502 is the photoelectric conversion device 100 described in any one of the first to fourth embodiments. The optical system 514 forms an optical image of an object on the photoelectric conversion device 502. The photoelectric conversion device 502 converts the optical image of the object formed by the optical system 514 into an electrical signal. The image preprocessing unit 515 performs predetermined signal processing on the signal output from the photoelectric conversion device 502. The function of the image preprocessing unit 515 may be incorporated in the photoelectric conversion device 502. At least two sets of the optical system 514, the photoelectric conversion device 502, and the image preprocessing unit 515 are provided in the photodetection system 501, and an output from the image preprocessing unit 515 of each set is input to the integrated circuit 503.

The integrated circuit 503 is an integrated circuit for an imaging system application and includes an image processing unit 504, an optical ranging unit 506, a parallax calculation unit 507, an object recognition unit 508, and an abnormality detection unit 509. The image processing unit 504 processes the image signal output from the image preprocessing unit 515. For example, the image processing unit 504 performs image processing such as development processing and defect correction on the output signal of the image preprocessing unit 515. The image processing unit 504 includes a memory 505 that temporarily holds the image signal. In the memory 505, for example, the position of a known defective pixel in the photoelectric conversion device 502 may be stored.

The optical ranging unit 506 performs focusing and distance measurement of the object. The parallax calculation unit 507 calculates distance measurement information (distance information) from a plurality of image data (parallax images) acquired by the plurality of photoelectric conversion devices 502. Each of the photoelectric conversion devices 502 may have a configuration capable of acquiring various kinds of information such as distance information. The object recognition unit 508 recognizes an object such as a vehicle, a road, a sign, or a person. Upon detecting an abnormality in the photoelectric conversion device 502, the abnormality detection unit 509 notifies the main control unit 513 of the abnormality.

The integrated circuit 503 may be realized by dedicatedly designed hardware, may be realized by a software module, or may be realized by a combination thereof. Further, it may be realized by a field programmable gate array (FPGA), an application specific integrated circuit (ASIC), or the like, or may be realized by a combination of these.

The main control unit 513 integrally controls the operations of the photodetection system 501, the vehicle sensor 510, the control unit 520, and the like. The vehicle 500 may not include the main control unit 513. In this case, the photoelectric conversion device 502, the vehicle sensor 510, and the control unit 520 transmit and receive control signals via a communication network. For example, the controller area network (CAN) standard may be applied to the transmission and reception of the control signals.

The integrated circuit 503 has a function of receiving a control signal from the main control unit 513 or transmitting a control signal or a setting value to the photoelectric conversion device 502 by its own control unit.

The photodetection system 501 is connected to the vehicle sensor 510, and may detect a traveling state of the host vehicle such as a vehicle speed, a yaw rate, and a steering angle, an environment outside the host vehicle, and states of other vehicles and obstacles. The vehicle sensor 510 is also a distance information acquisition unit that acquires distance information to the object. In addition, the photodetection system 501 is connected to a driving support control unit 511 that performs various kinds of driving support such as automatic steering, automatic traveling, and a collision prevention function. In particular, with respect to the collision determination function, the driving support control unit 511 estimates the collision with other vehicles or obstacles and determines whether or not there is a collision with other vehicles or obstacles based on the detection results of the photodetection system 501 and the vehicle sensor 510. Thus, avoidance control when a collision is estimated and activation of the safety device at the time of the collision are performed.

The photodetection system 501 is also connected to an alert device 512 that issues an alert to the driver based on the determination result of the collision determination unit. For example, when the determination result of the collision determination unit is that the possibility of a collision is high, the main control unit 513 performs vehicle control for avoiding a collision and reducing damage by applying a brake, returning an accelerator, suppressing engine output, or the like. The alert device 512 alerts the user by sounding an alarm such as a sound, displaying alert information on a display screen of a car navigation system, a meter panel, or the like, or vibrating a seat belt or a steering wheel.

In the present embodiment, an image of the surroundings of the vehicle, for example, the front or the rear, is captured by the photodetection system 501. FIG. 17B illustrates an arrangement example of the photodetection system 501 in a case where the photodetection system 501 captures an image of a region in front of the vehicle.

As described above, the photoelectric conversion devices 502 are disposed in front of the vehicle 500. Specifically, it is preferable that a center line with respect to an advancing/retreating direction or an outer shape (for example, a vehicle width) of the vehicle 500 is regarded as a symmetry axis, and two photoelectric conversion devices 502 are disposed line-symmetrically with respect to the symmetry axis in order to acquire distance information between the vehicle 500 and an object to be imaged and determine a possibility of collision. In addition, the photoelectric conversion devices 502 are preferably disposed so as not to interfere with the driver's visual field when the driver visually recognizes a situation outside the vehicle 500 from the driver's seat. The alert device 512 is preferably disposed so as to easily enter the field of view of the driver.

Next, a failure detection operation of the photoelectric conversion device 502 in the photodetection system 501 will be described with reference to FIG. 19. The failure detection operation of the photoelectric conversion device 502 may be performed in accordance with steps S110 to S180 illustrated in FIG. 19.

Step S110 is a step of performing setting at the time of start-up of the photoelectric conversion device 502. That is, the setting for the operation of the photoelectric conversion device 502 is transmitted from the outside of the photodetection system 501 (for example, the main control unit 513) or the inside of the photodetection system 501, and the imaging operation and the failure detection operation of the photoelectric conversion device 502 are started.

Next, in step S120, pixel signals are acquired from the effective pixels. In step S130, an output value from a failure detection pixel provided for failure detection is acquired. The failure detection pixel may include a photoelectric conversion element in the same manner as the effective pixel. A predetermined voltage is written to the photoelectric conversion element of the failure detection pixel. The failure detection pixel outputs a signal corresponding to the voltage written in the photoelectric conversion element. Note that step S120 and step S130 may be reversed.

Next, in step S140, a classification of the output expected value of the failure detection pixel and the actual output value from the failure detection pixel is performed. As a result of the classification in step S140, when the output expected value matches the actual output value, the process proceeds to step S150, it is determined that the imaging operation is normally performed, and the process step proceeds to step S160. In step S160, the pixel signals of the scanning row are transmitted to the memory 505 and temporarily stored. After that, the process returns to step S120 to continue the failure detection operation. On the other hand, as a result of the classification in step S140, when the output expected value does not coincide with the actual output value, the process proceeds to step S170. In step S170, it is determined that there is an abnormality in the imaging operation, and an alert is notified to the main control unit 513 or the alert device 512. The alert device 512 causes the display unit to display that an abnormality has been detected. Thereafter, in step S180, the photoelectric conversion device 502 is stopped, and the operation of the photodetection system 501 is ended.

In the present embodiment, an example in which the flowchart is looped for each row is described, but the flowchart may be looped for each plurality of rows, or the failure detection operation may be performed for each frame. The alert of step S170 may be notified to the outside of the vehicle via a wireless network.

In addition, in the present embodiment, the control in which the own vehicle does not collide with another vehicle has been described, but the present disclosure is also applicable to control in which the own vehicle follows another vehicle and performs automatic driving, control in which the vehicle performs automatic driving so as not to protrude from a lane, and the like. Further, the photodetection system 501 is not limited to a vehicle such as an own vehicle and may be applied to, for example, other movable object (mobile device) of a ship, an aircraft, an industrial robot, or the like. In addition, the present disclosure is not limited to the movable object and may be widely applied to equipment using object recognition, such as intelligent transport systems (ITS).

### Ninth Embodiment

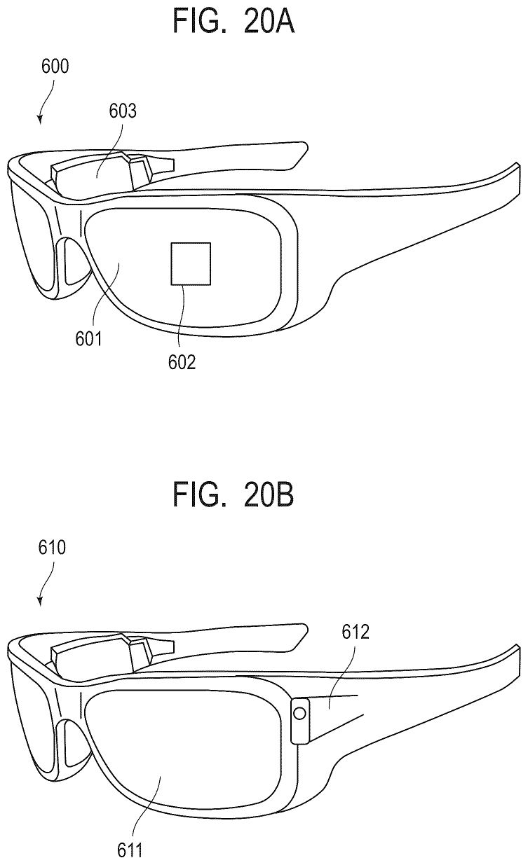

A photodetection system according to a ninth embodiment will be described with reference to FIG. 20A and FIG. 20B. FIG. 20A and FIG. 20B are schematic diagrams illustrating configuration examples of the photodetection system according to the present embodiment. In the present embodiment, an application example to eyeglasses (smart glasses) will be described as a photodetection system to which the photoelectric conversion device 100 according to any one of the first to fourth embodiments is applied.

FIG. 20A illustrates eyeglasses 600 (smart glasses) according to one application example. The eyeglasses 600 include lenses 601, a photoelectric conversion device 602, and a control device 603.

The photoelectric conversion device 602 is the photoelectric conversion device 100 described in any one of the first to fourth embodiments and is provided on the lens 601. One photoelectric conversion device 602 may be provided, or a plurality of photoelectric conversion devices may be provided. When a plurality of photoelectric conversion devices 602 are used, a combination of a plurality of types of photoelectric conversion devices 602 may be used. The arrangement position of the photoelectric conversion device 602 is not limited to FIG. 20A. A display device (not illustrated) including a light emitting device such as an organic light emitting diode (OLED) or a light emitting diode (LED) may be provided on the back surface side of the lens 601.

The control device 603 functions as a power supply that supplies power to the photoelectric conversion device 602 and the display device. The control device 603 has a function of controlling the operations of the photoelectric conversion device 602 and the display device. The lens 601 may be provided with an optical system for focusing light on the photoelectric conversion device 602.

FIG. 20B illustrates eyeglasses 610 (smart glasses) according to another application example. The eyeglasses 610 include lenses 611 and a control device 612. A photoelectric conversion device (not illustrated) corresponding to the photoelectric conversion device 602 and the display device may be mounted on the control device 612. The lens 611 is provided with a photoelectric conversion device in the control device 612 and an optical system for projecting light from the display device, and an image is projected thereon. The control device 612 functions as a power supply that supplies power to the photoelectric conversion device and the display device and has a function of controlling operations of the photoelectric conversion device and the display device.

The control device 612 may further include a line-of-sight detection unit that detects the line-of-sight of the wearer. In this case, an infrared light emitting unit may be provided in the control device 612, and infrared light emitted from the infrared light emitting unit may be used for detection of a line of sight. Specifically, the infrared light emitting unit emits infrared light to the eyeball of the user who is watching at the display image. A captured image of the eyeball is obtained by detecting reflected light of the emitted infrared light from the eyeball by an imaging unit having a light receiving element. By providing a reduction unit that reduces light from the infrared light emitting unit to the display unit in a plan view, it is possible to reduce degradation of image quality.

The line of sight of the user with respect to the display image may be detected from the captured image of the eyeball obtained by capturing the infrared light. Any known technique may be applied to the line-of-sight detection using the captured image of the eyeball. As an example, a line-of-sight detection method based on a Purkinje image due to reflection of irradiation light on the cornea may be used. More specifically, the line-of-sight detection process based on the pupil corneal reflection method is performed. The line of sight of the user may be detected by calculating a line-of-sight vector representing the orientation (rotation angle) of the eyeball based on the image of the pupil included in the captured image of the eyeball and the Purkinje image using the pupil corneal reflex method.

The display device according to the present embodiment may include a photoelectric conversion device having a light receiving element and may be configured to control a display image based on line-of-sight information of a user from the photoelectric conversion device. Specifically, the display device determines, based on the line-of-sight information, a first viewing area that the user gazes at and a second viewing area other than the first viewing area. The first viewing area and the second viewing area may be determined by a control device of the display device or may be determined by an external control device. When the determination is made by the external control device, the determination result is transmitted to the display device via communication. In the display area of the display device, the display resolution of the first viewing area may be controlled to be higher than the display resolution of the second viewing area. That is, the resolution of the second viewing area may be lower than the resolution of the first viewing area.

The display area may include a first display area and a second display area different from the first display area, and an area having a high priority may be determined from the first display area and the second display area based on the line-of-sight information. The first display area and the second display area may be determined by a control device of the display device or may be determined by an external control device. When the determination is made by the external control device, the determination result is transmitted to the display device via communication. The resolution of the high priority area may be controlled to be higher than the resolution of the area other than the high priority area. That is, the resolution of the area having a relatively low priority may be lowered.

Note that an artificial intelligence (AI) may be used to determine the first viewing area or the area with a high priority. The AI may be a model configured to estimate an angle of the line of sight and a distance to a target object ahead of the line of sight from the image of the eyeball using the image of the eyeball and the direction in which the eyeball of the image is actually viewed as teacher data. The AI program may be included in the display device, the photoelectric conversion device, or the external device. When the external device has the program, the information may be transmitted to the display device via communication.

In the case of performing display control based on visual recognition detection, the present disclosure may be preferably applied to smart glasses further including a photoelectric conversion device that captures an image of the outside. Smart glasses may display captured external information in real time.

### Modified Embodiments

The present disclosure is not limited to the above embodiments, and various modifications are possible.

For example, an example in which a part of the configuration of any of the embodiments is added to another embodiment or an example in which a part of the configurations of any of the embodiments is substituted with some of the configurations of another embodiment is also an embodiment of the present disclosure.

Further, the circuit configuration of the pixel 12 is not limited to the above-described embodiment. For example, a switch such as a transistor may be provided between the photoelectric conversion element 22 and the quenching circuit 32 or between the photoelectric conversion element 22 and the signal processing unit 30 to control the electrical connection state therebetween. In addition, a switch such as a transistor may be provided between the node to which the voltage VH is supplied and the quenching circuit 32 and/or between the node to which the voltage VL is supplied and the photoelectric conversion element 22 to control an electrical connection state therebetween. A plurality of photoelectric conversion elements 22 may be provided for one pixel 12.

Further, in the circuit configuration of the pixel 12 of the above-described embodiment, the signal charge (electrons) is taken out from the cathode side with the anode side of the APD as the fixed potential, but the signal charge (holes) may be taken out from the anode side with the cathode side of the APD as the fixed potential.

Further, in the above embodiment, a configuration in which a counter circuit is used as the processing circuit 36 has been described, but a time to digital converter (TDC) and a memory may be used instead of the counter circuit. In this case, the generation timing of the pulse signal output from the waveform shaping circuit 34 is converted into a digital signal by the TDC. A control pulse pREF (reference signal) is supplied to the TDC from the vertical scanning circuit unit 40 via the control line 14 when the timing of the pulse signal is measured. The TDC acquires, as a digital signal, a signal when an input timing of a signal output from each pixel 12 is set to a relative time with reference to the control pulse pREF.

According to the present disclosure, in a photoelectric conversion device configured by stacking a plurality of substrates, noise caused by a through-hole or a through-electrode may be effectively reduced.

### Other Embodiments

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-203974, filed Nov. 22, 2024, which is hereby incorporated by reference herein in its entirety.

What is claimed is:

1. A photoelectric conversion device comprising:
a first semiconductor layer provided with a photoelectric conversion element;
a second semiconductor layer having a first face and a second face opposite to the first face and provided with an element electrically connected to the photoelectric conversion element on the first face;
a through-electrode provided in a through-hole penetrating the second semiconductor layer;
a fixed charge containing layer provided in contact with an inner face of the through-hole;
a first insulating layer provided between the fixed charge containing layer and the through-electrode; and
a second insulating layer including an insulating material and provided in contact with the second face and the fixed charge containing layer.

2. The photoelectric conversion device according to claim 1, wherein the first semiconductor layer is arranged so as to face the first face.

3. The photoelectric conversion device according to claim 1, wherein the first semiconductor layer is arranged so as to face the second face.

4. The photoelectric conversion device according to claim 3, further comprising a third insulating layer made of an insulating material having a refractive index higher than that of the second insulating layer,
wherein the second insulating layer is arranged between the second semiconductor layer and the third insulating layer.

5. The photoelectric conversion device according to claim 2, further comprising a first interconnection structure layer arranged on a side of the first face of the second semiconductor layer,
wherein the second semiconductor layer is electrically connected to the first semiconductor layer via the first interconnection structure layer.

6. The photoelectric conversion device according to claim 5, wherein the first interconnection structure layer includes a connection member connected to the through-electrode.

7. The photoelectric conversion device according to claim 3, further comprising a first interconnection structure layer arranged on a side of the second face of the second semiconductor layer,
wherein the second semiconductor layer is electrically connected to the first semiconductor layer via the first interconnection structure layer.

8. The photoelectric conversion device according to claim 5, further comprising a second interconnection structure layer arranged between a third face of the first semiconductor layer facing the second semiconductor layer and the first interconnection structure layer,
wherein the first interconnection structure layer and the second interconnection structure layer are electrically connected to each other by a metal-metal bonding between a metal interconnection included in the first interconnection structure layer and a metal interconnection included in the second interconnection structure layer.

9. The photoelectric conversion device according to claim 8, further comprising an optical structure layer arranged on a fourth face opposite to the third face of the first semiconductor layer,
wherein the photoelectric conversion element is configured to receive light incident through the optical structure layer.

10. The photoelectric conversion device according to claim 5, further comprising a third interconnection structure layer arranged on a side of the second face of the second semiconductor layer.

11. The photoelectric conversion device according to claim 7, further comprising a third interconnection structure layer arranged on a side of the first face of the second semiconductor layer.

12. The photoelectric conversion device according to claim 11, wherein the third interconnection structure layer includes a connection member connected to the through-electrode.

13. The photoelectric conversion device according to claim 1, wherein the through-hole penetrates the second semiconductor layer and the second insulating layer.

14. The photoelectric conversion device according to claim 1, wherein an opening width of the through-hole at the second face is wider than an opening width of the through-hole at the first face.

15. The photoelectric conversion device according to claim 1, wherein a thickness of the first insulating layer on a side of the first face is thicker than a thickness of the first insulating layer on a side of the second face.

16. The photoelectric conversion device according to claim 1,
wherein the second semiconductor layer includes a first semiconductor region of a first conductivity type and a second semiconductor region of a second conductivity type different from the first conductivity type, and
wherein the second insulating layer is in contact with the first semiconductor region and the second semiconductor region.

17. The photoelectric conversion device according to claim 16,
wherein the second semiconductor layer includes a third semiconductor region arranged around the through-hole, and a fourth semiconductor region arranged between the third semiconductor region and the first semiconductor region or the second semiconductor region, and
wherein an impurity concentration of the fourth semiconductor region is lower than an impurity concentration of the third semiconductor region.

18. The photoelectric conversion device according to claim 1, further comprising a third semiconductor layer arranged so that the second semiconductor layer is arranged between the first semiconductor layer and the third semiconductor layer.

19. The photoelectric conversion device according to claim 1, wherein the fixed charge containing layer includes hafnium oxide, zirconium oxide, aluminum oxide, titanium oxide, or tantalum oxide.

20. The photoelectric conversion device according to claim 1, wherein the second insulating layer includes silicon oxide, silicon nitride, silicon oxynitride, silicon carbide, or silicon carbonitride.

21. A photodetection system comprising:
the photoelectric conversion device according to claim 1; and
a signal processing device configured to process a signal output from the photoelectric conversion device.

22. The photodetection system according to claim 21, wherein the signal processing device generates a distance image representing distance information to an object based on the signal.

23. A movable object comprising:
the photoelectric conversion device according to claim 1;
a distance information acquisition device configured to acquire distance information to an object from a parallax image based on a signal output from the photoelectric conversion device; and
a control device configured to control the movable object based on the distance information.
